(19) United States
(12) Patent Application Publication
(10) Pub. No.: US 2025/0357340 A1
(43) Pub. Date: Nov. 20, 2025

(54) INTEGRATED CIRCUIT STRUCTURES AND METHODS OF FORMING THE SAME

(71) Applicant: Taiwan Semiconductor Manufacturing Company, Ltd., Hsinchu (TW)

(72) Inventors: Kuo-Chiang Ting, Hsinchu City (TW); Sung-Feng Yeh, Taipei City (TW); Ta-Hao Sung, Yilan County (TW); Shin-Jiun Fu, Hsinchu City (TW)

(73) Assignee: Taiwan Semiconductor Manufacturing Company, Ltd., Hsinchu (TW)

(21) Appl. No.: 19/281,728

(22) Filed: Jul. 27, 2025

Related U.S. Application Data
(63) Continuation of application No. 18/590,972, filed on Feb. 29, 2024.

(51) Int. Cl. H01L 23/528; H01L 21/768; H01L 23/373; H01L 23/522

(52) U.S. Cl. CPC H01L 23/5283; H01L 21/76897; H01L 23/3738; H01L 23/5226

(57) ABSTRACT

An integrated circuit structure includes a first die, a second die and the a heat dissipation structure. The first die includes a first device layer, a first front-side interconnect structure disposed on a front side of the first device layer, and a first backside interconnect structure disposed on a backside of the first device layer. The second die is bonded to the first die and includes a second device layer, and a second front-side interconnect structure disposed on a front side of the second device layer. The heat dissipation structure is in direct contact to the first die or the second die.

### CROSS-REFERENCE TO RELATED APPLICATION

This application is a continuation application of and claims the priority benefit of U.S. patent application Ser. No. 18/590,972, filed on Feb. 29, 2024. The entirety of the above-mentioned patent application is hereby incorporated by reference herein and made a part of this specification.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Although the existing integrated circuit structures have been generally adequate for their intended purposes, they have not been entirely satisfactory in every aspect. For example, the heat dissipation is a challenge in a variety of integrated circuit structures.

### BRIEF DESCRIPTION OF THE DRA WINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

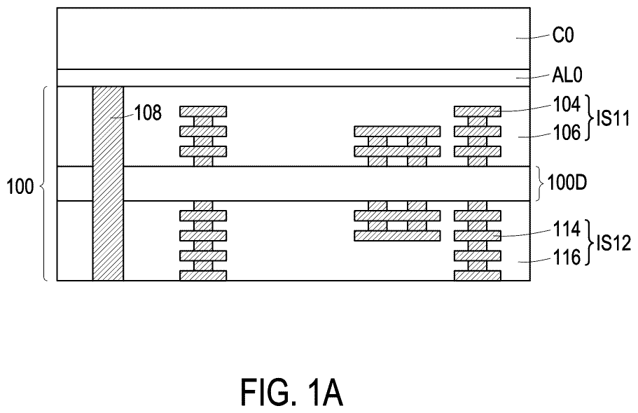

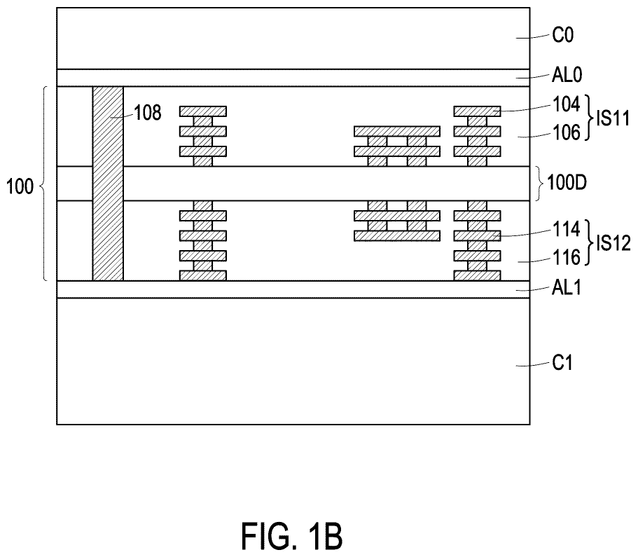

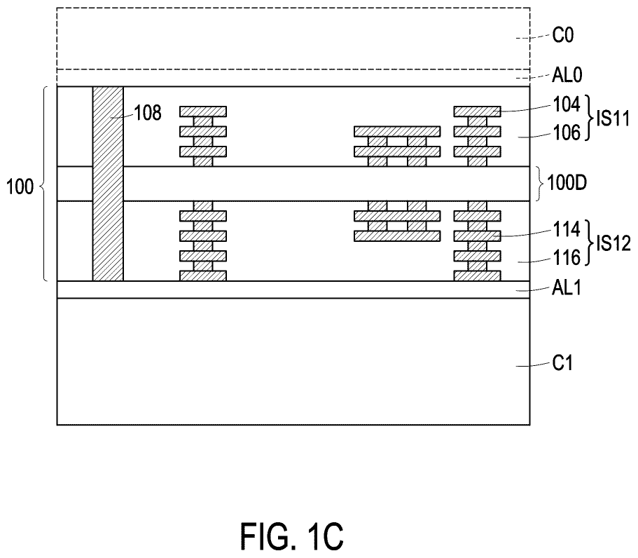

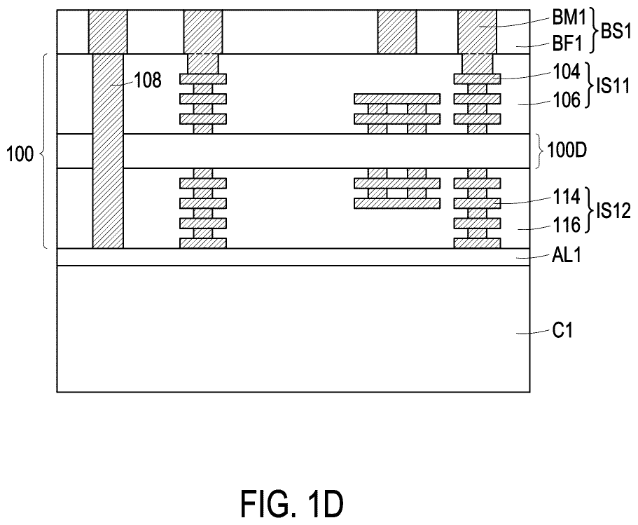

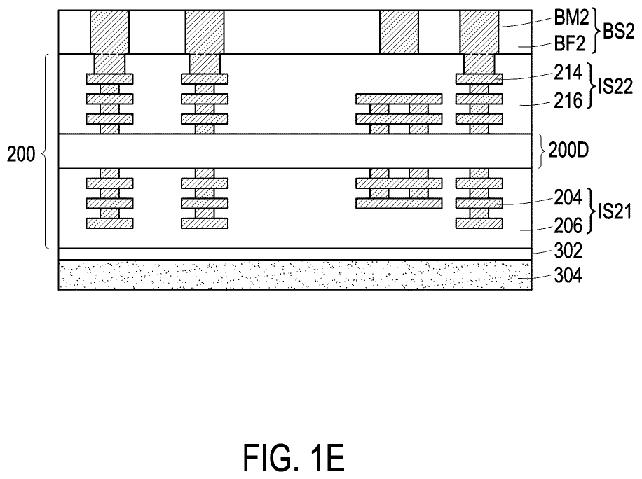

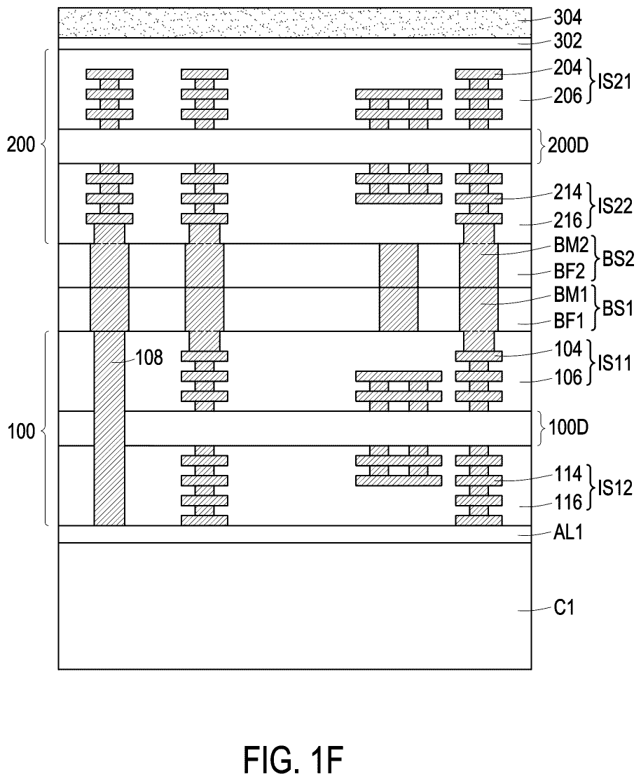

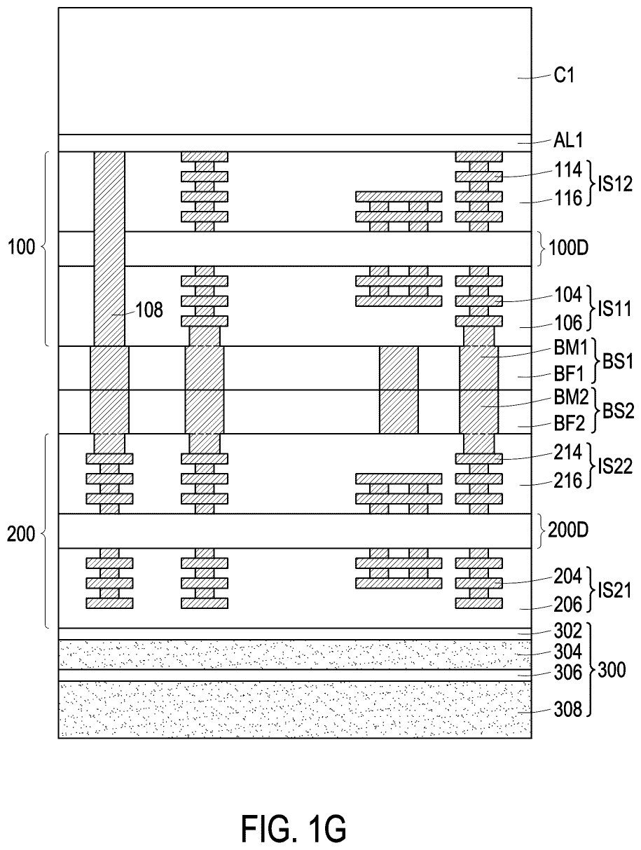

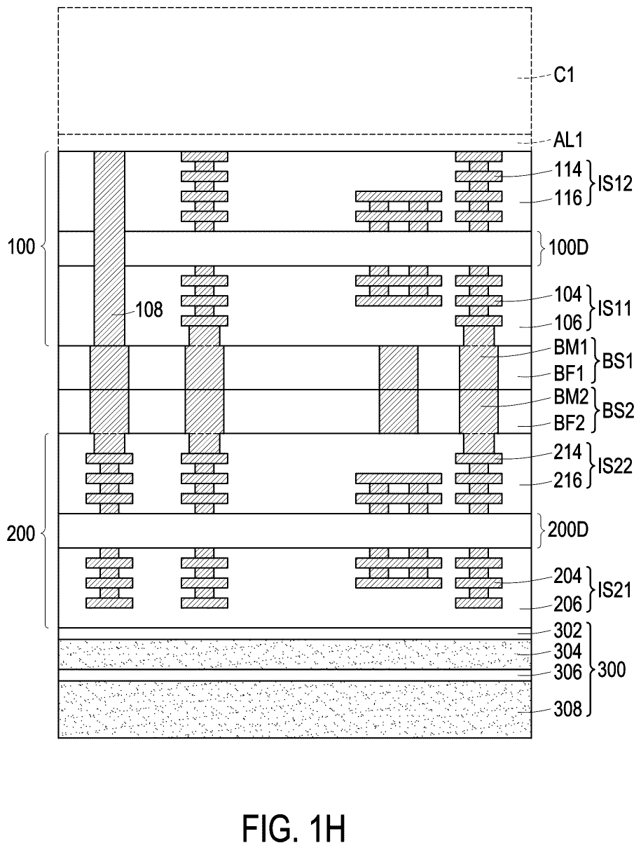

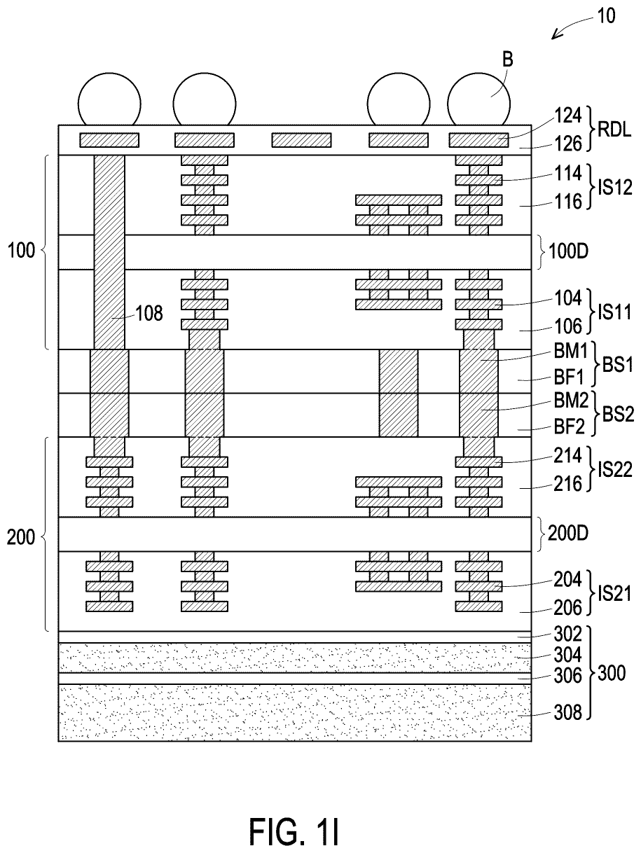

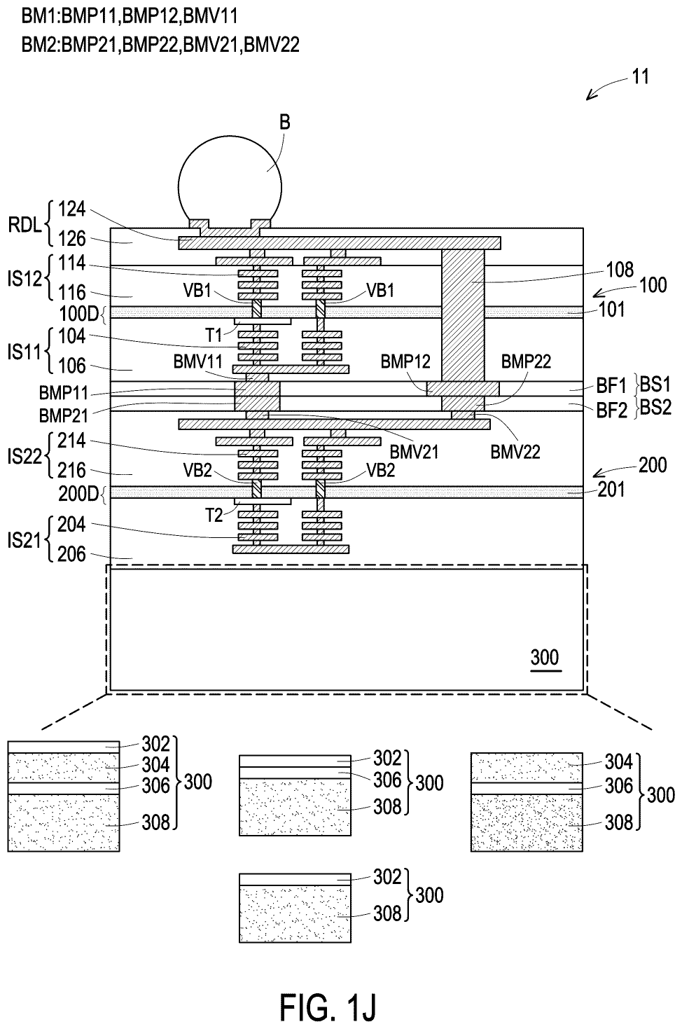

FIG. 1A to FIG. 1I illustrate cross-sectional views of a method of forming an integrated circuit structure in accordance with some embodiments of the present disclosure.

FIG. 1J illustrates a cross-sectional view of an integrated circuit structure in accordance with some embodiments of the present disclosure.

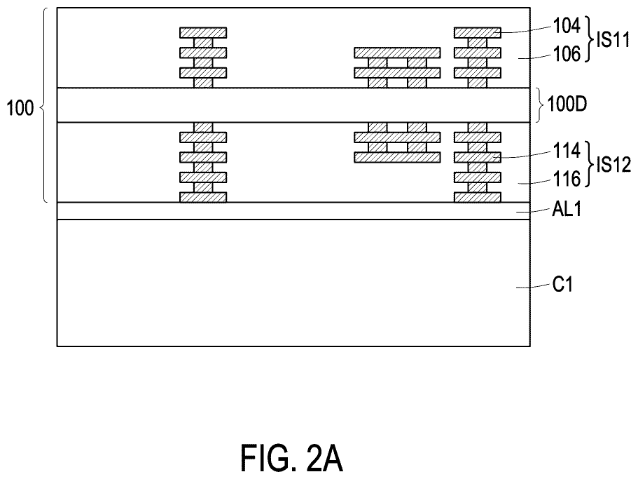

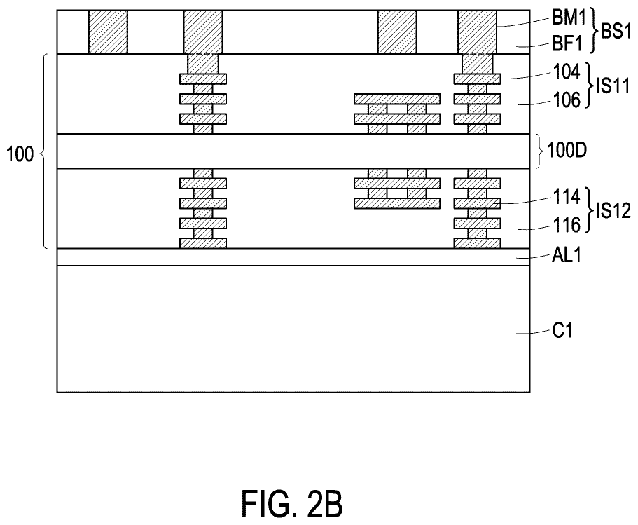

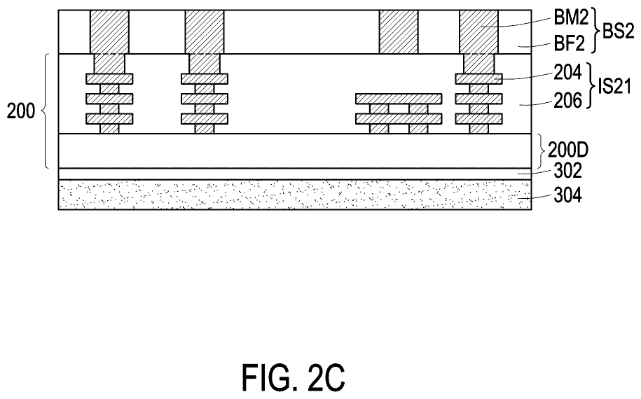

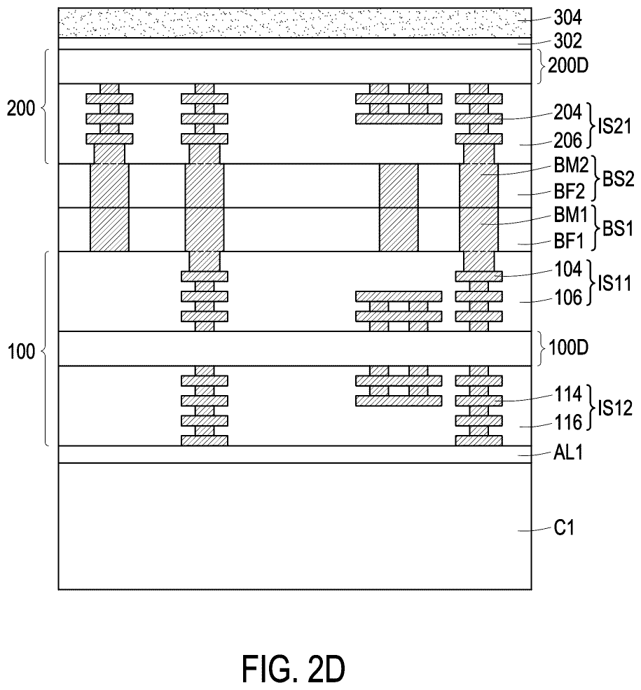

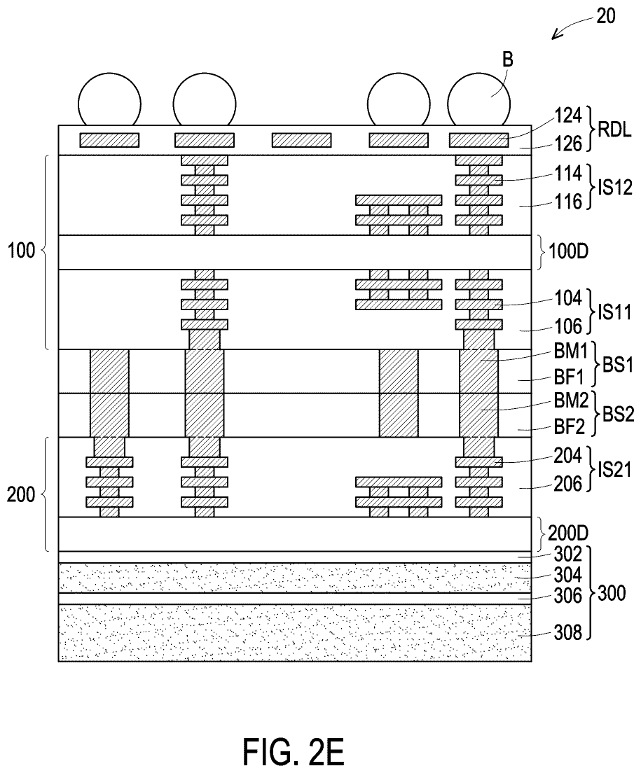

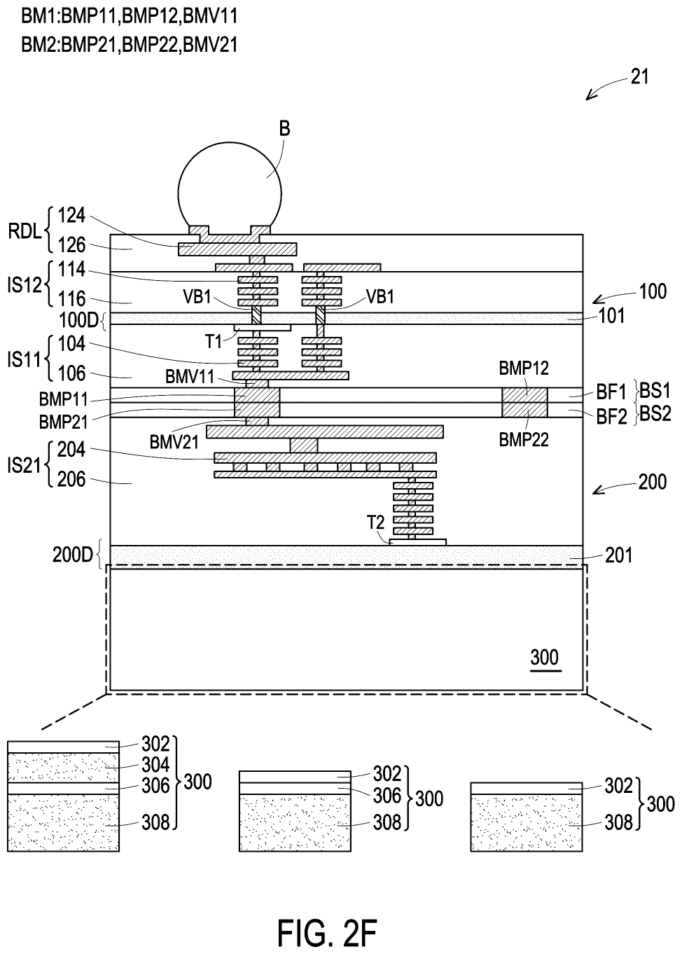

FIG. 2A to FIG. 2E illustrate cross-sectional views of a method of forming an integrated circuit structure in accordance with some embodiments of the present disclosure.

FIG. 2F illustrates a cross-sectional view of an integrated circuit structure in accordance with some embodiments of the present disclosure.

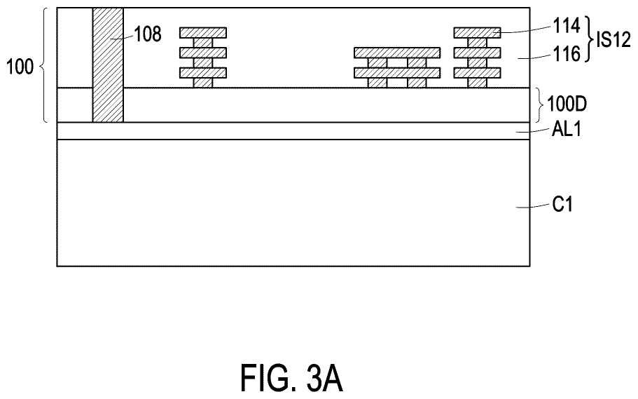

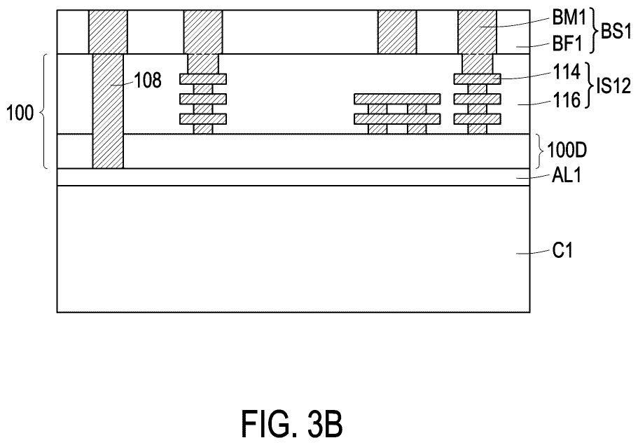

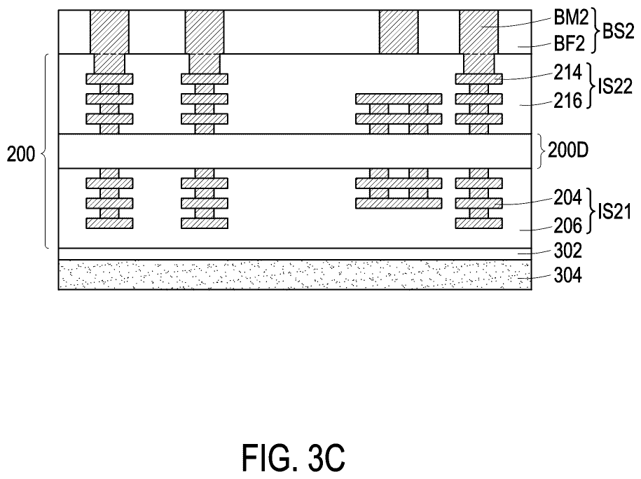

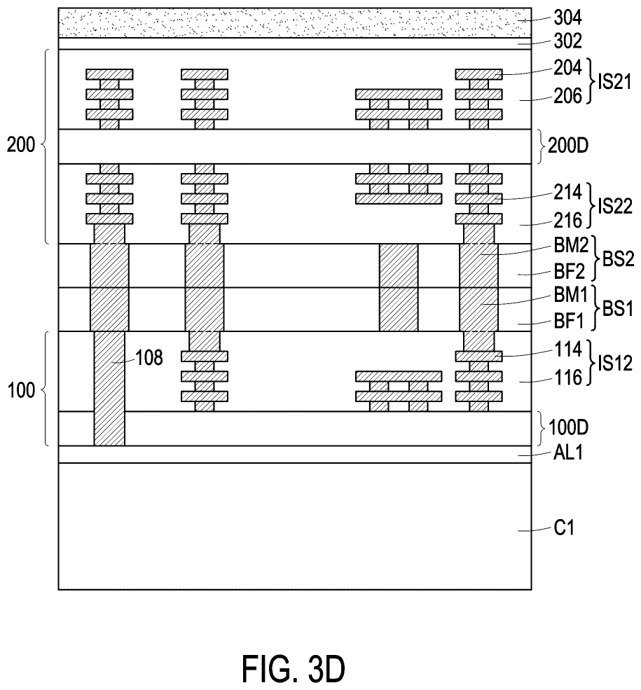

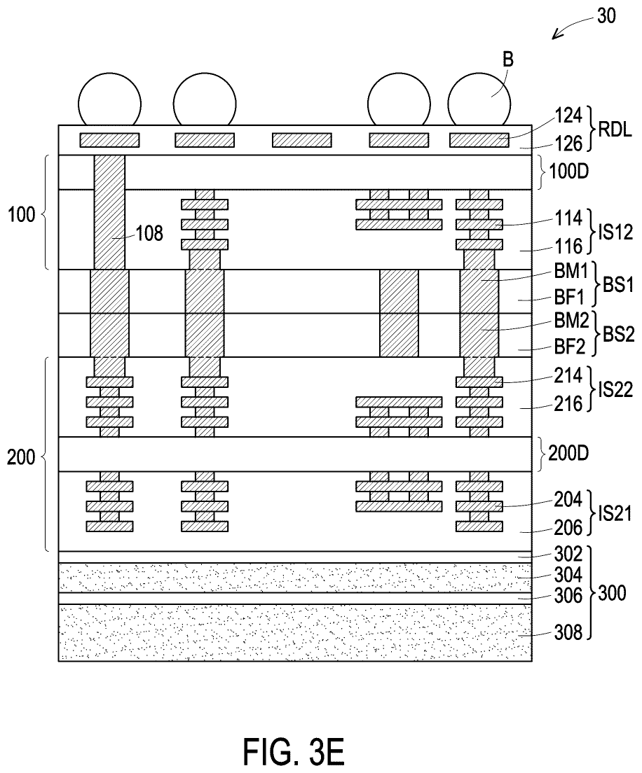

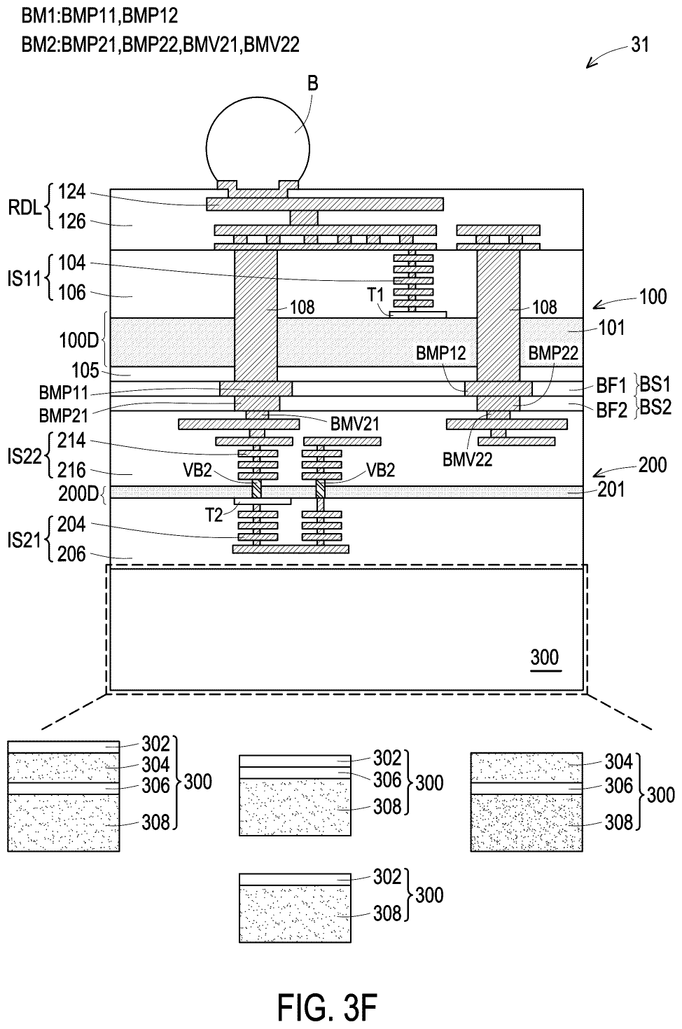

FIG. 3A to FIG. 3E illustrate cross-sectional views of a method of forming an integrated circuit structure in accordance with some embodiments of the present disclosure.

FIG. 3F illustrates a cross-sectional view of an integrated circuit structure in accordance with some embodiments of the present disclosure.

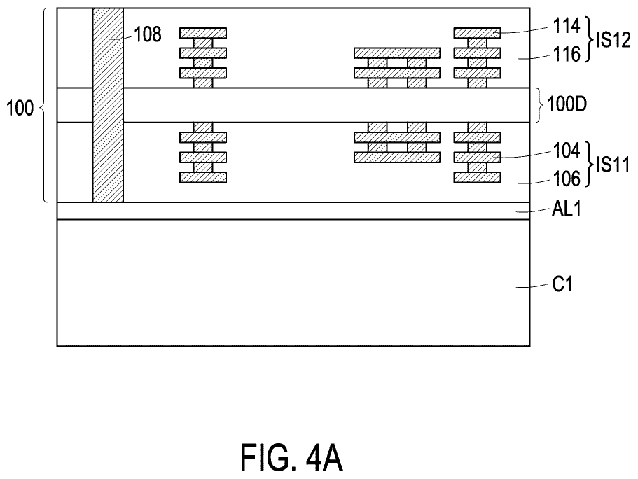

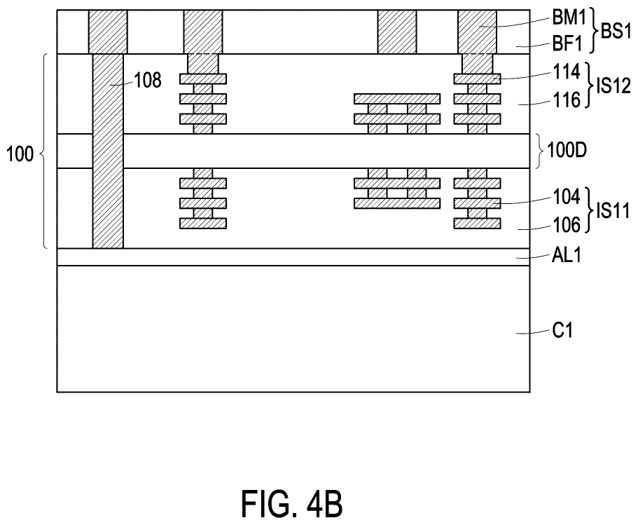

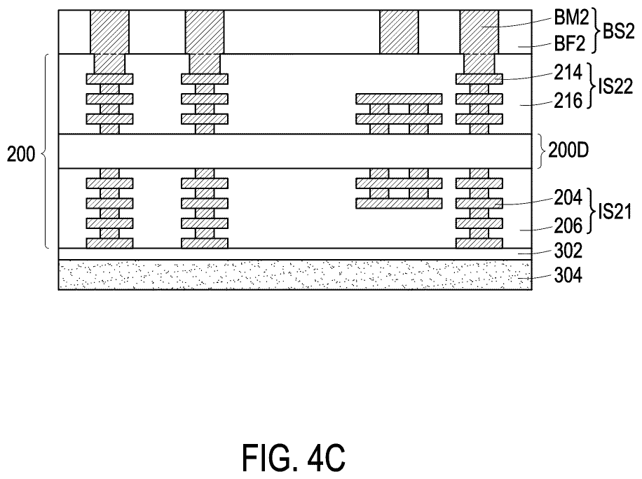

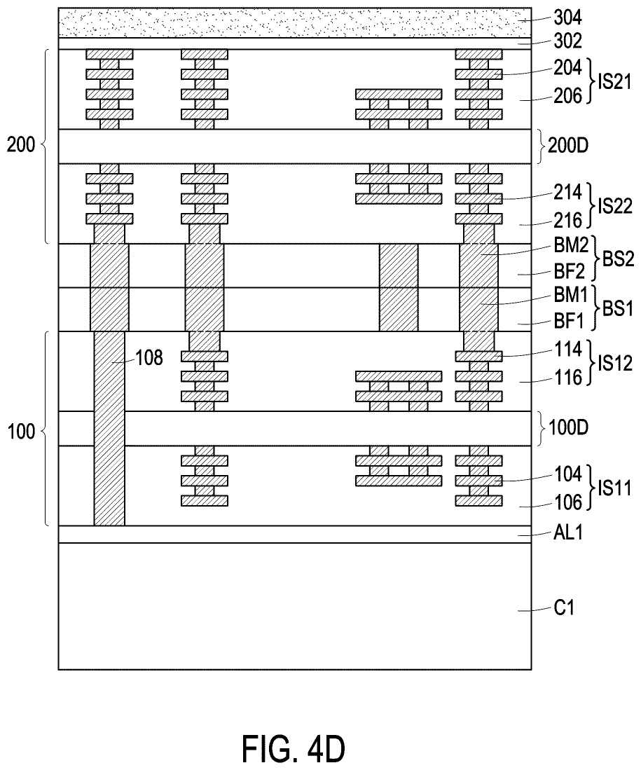

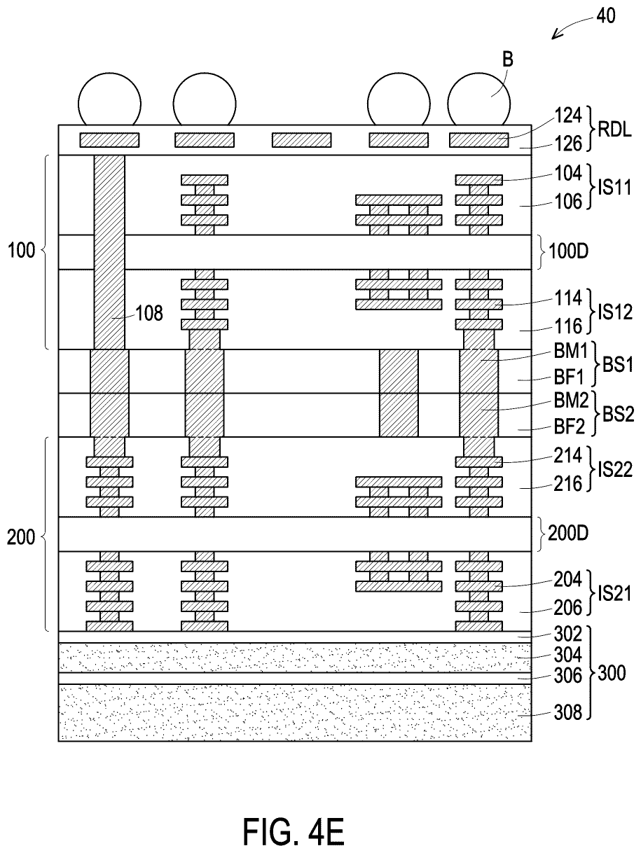

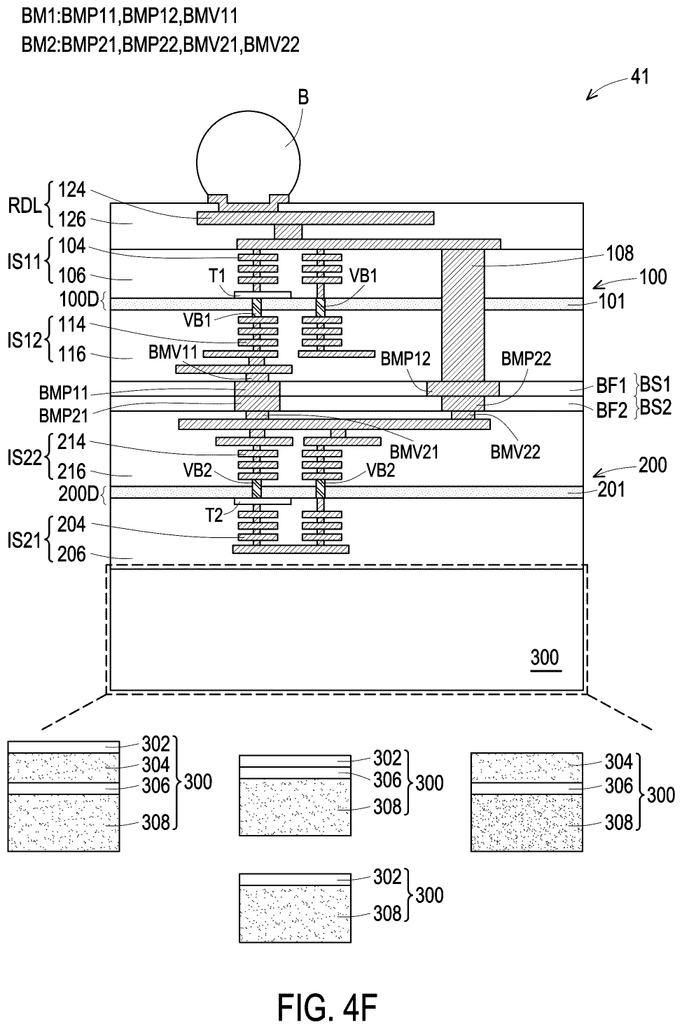

FIG. 4A to FIG. 4E illustrate cross-sectional views of a method of forming an integrated circuit structure in accordance with some embodiments of the present disclosure.

FIG. 4F illustrates a cross-sectional view of an integrated circuit structure in accordance with some embodiments of the present disclosure.

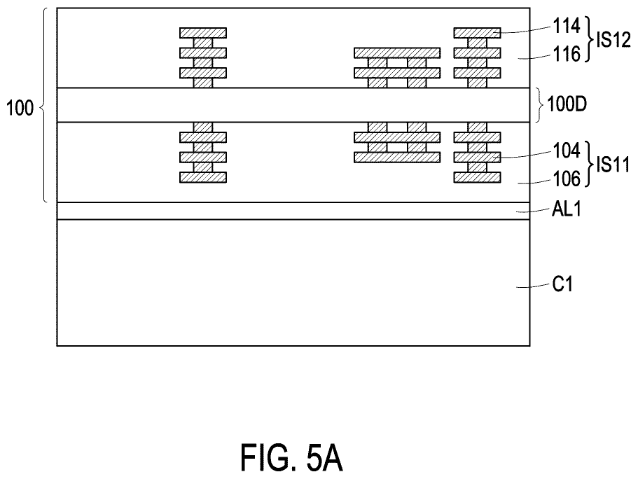

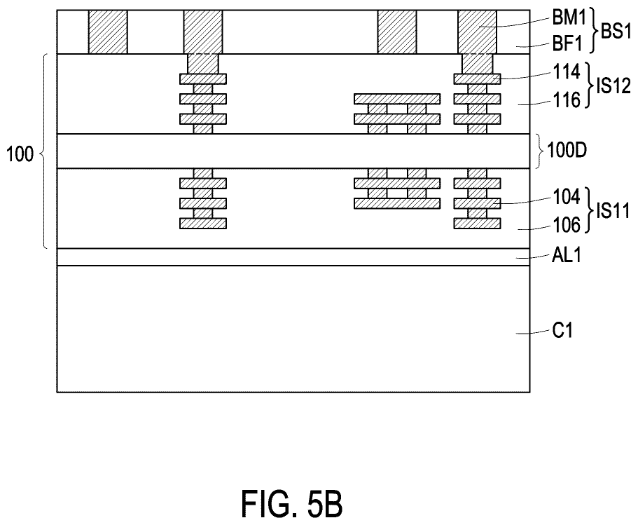

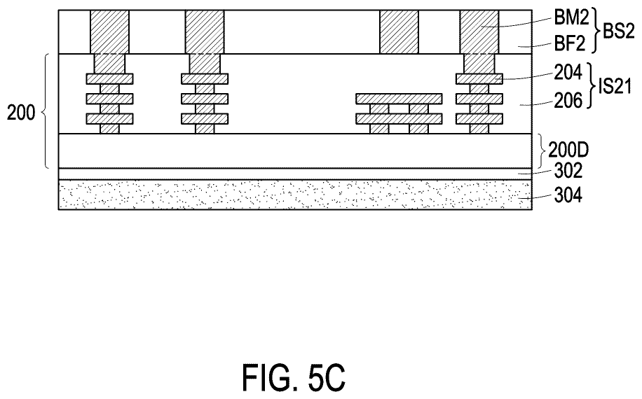

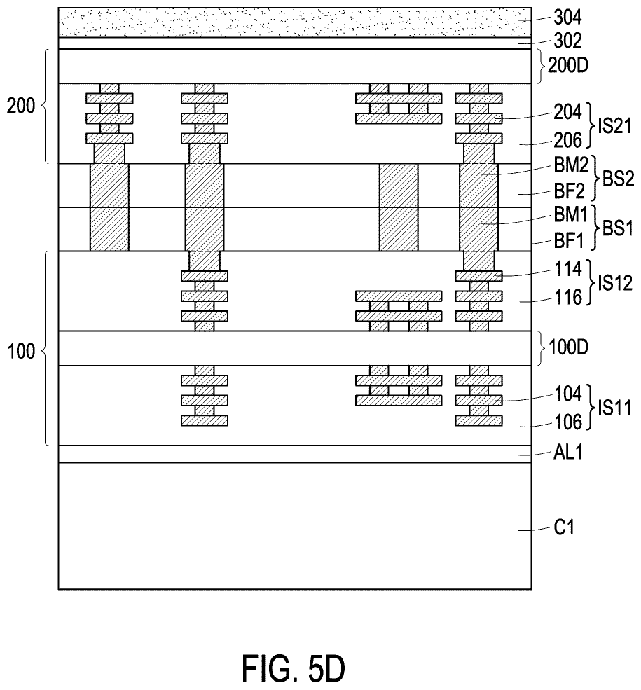

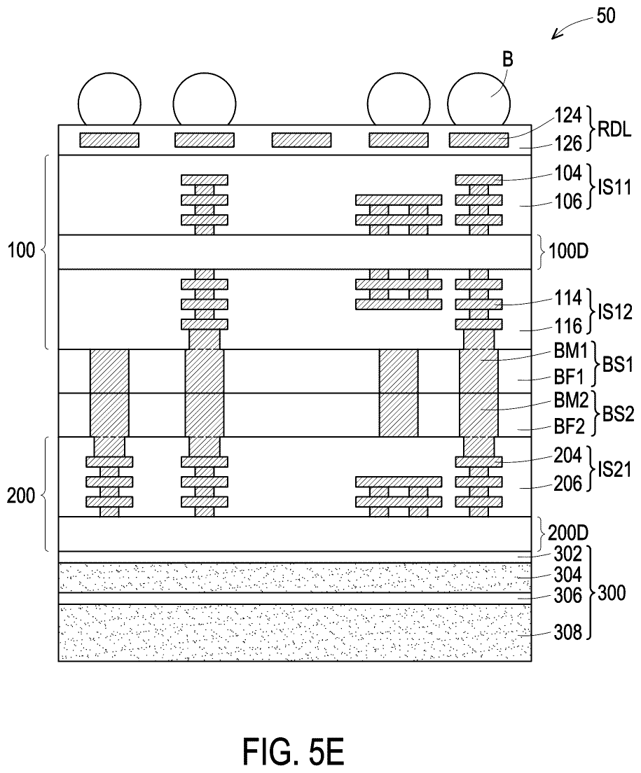

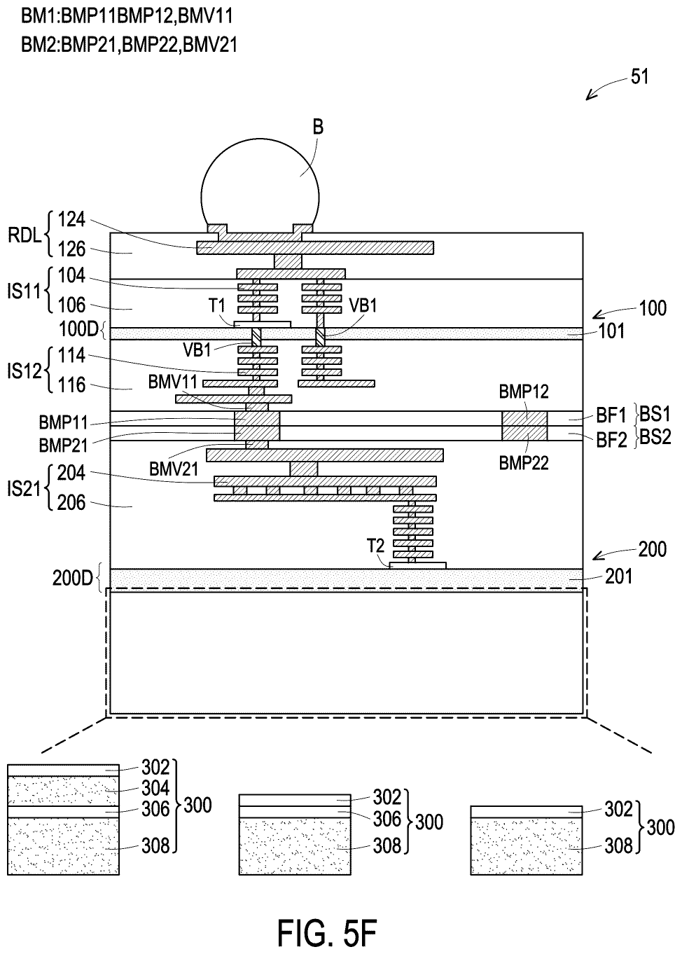

FIG. 5A to FIG. 5E illustrate cross-sectional views of a method of forming an integrated circuit structure in accordance with some embodiments of the present disclosure.

FIG. 5F illustrates a cross-sectional view of an integrated circuit structure in accordance with some embodiments of the present disclosure.

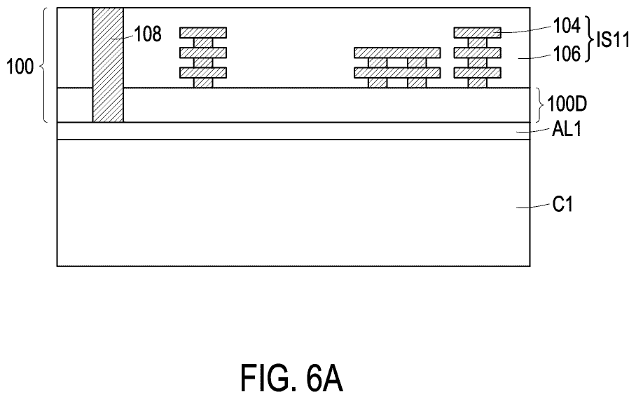

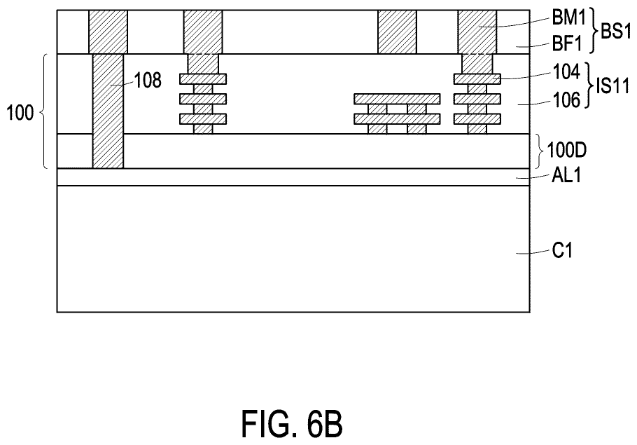

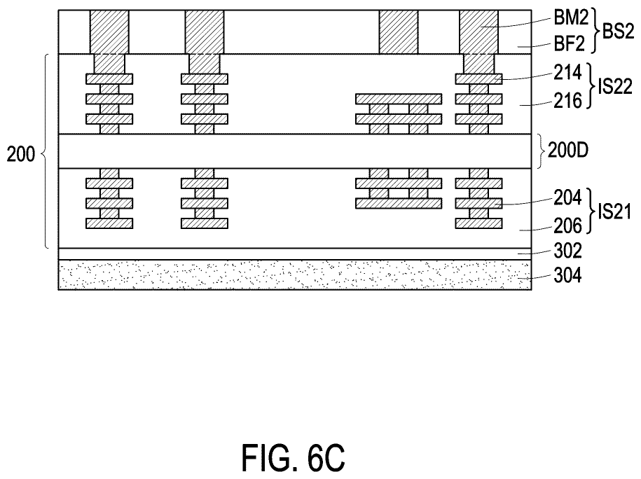

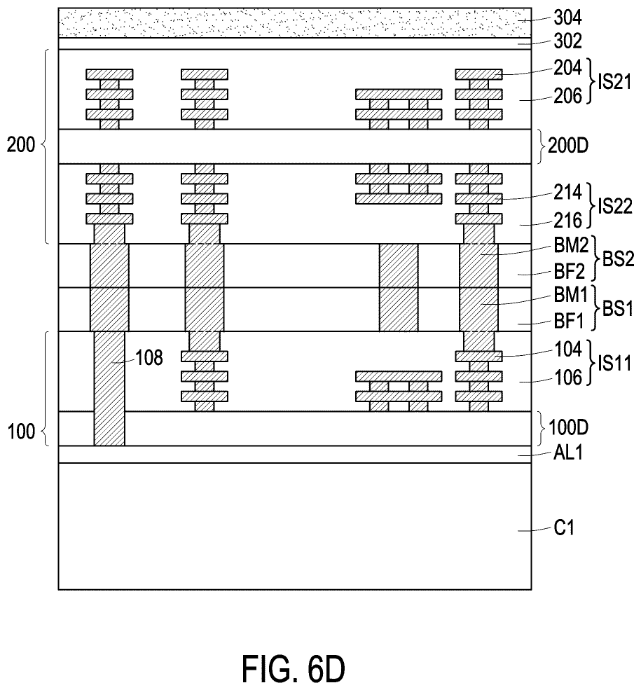

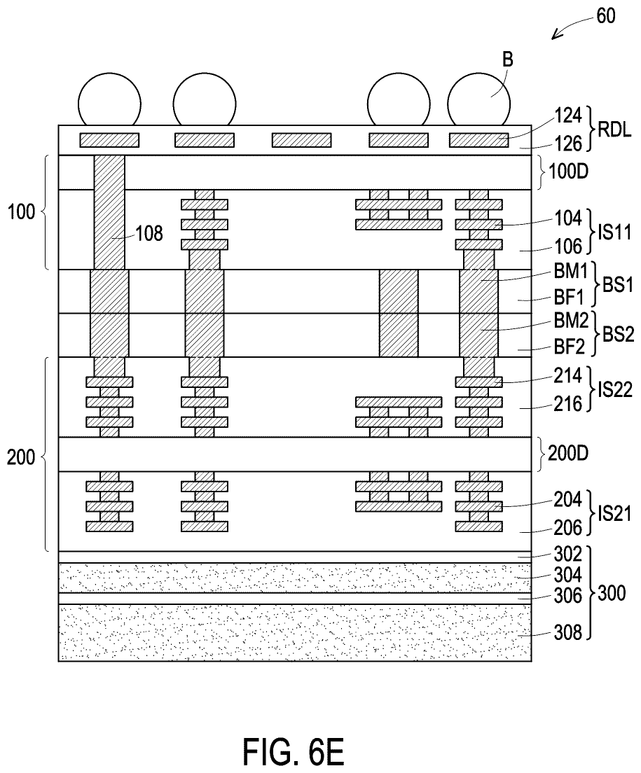

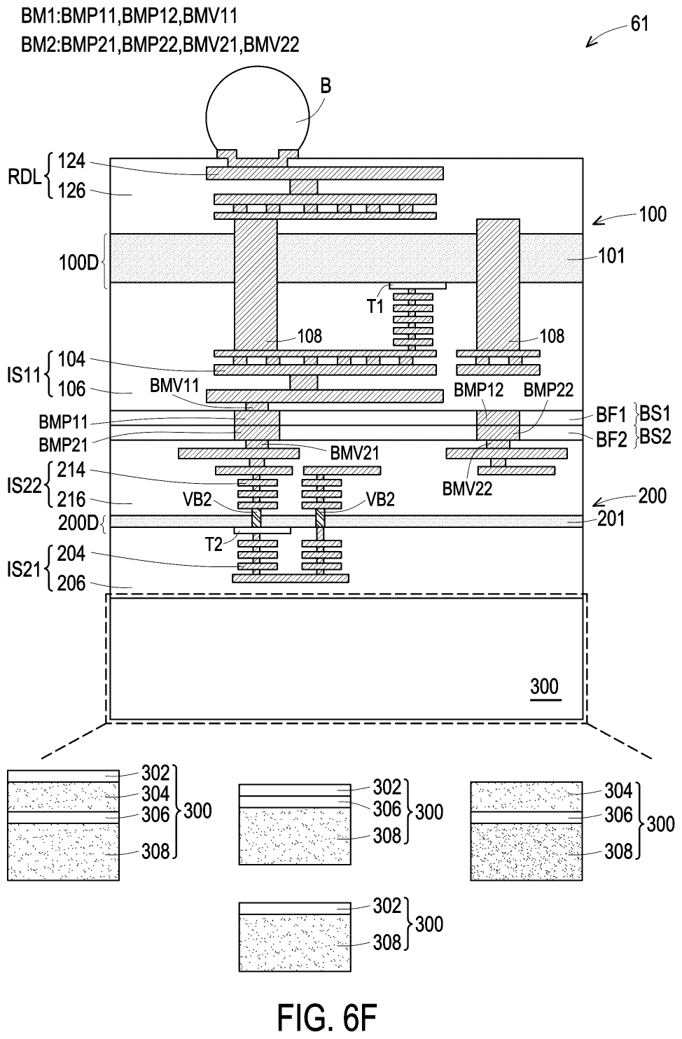

FIG. 6A to FIG. 6E illustrate cross-sectional views of a method of forming an integrated circuit structure in accordance with some embodiments of the present disclosure.

FIG. 6F illustrates a cross-sectional view of an integrated circuit structure in accordance with some embodiments of the present disclosure.

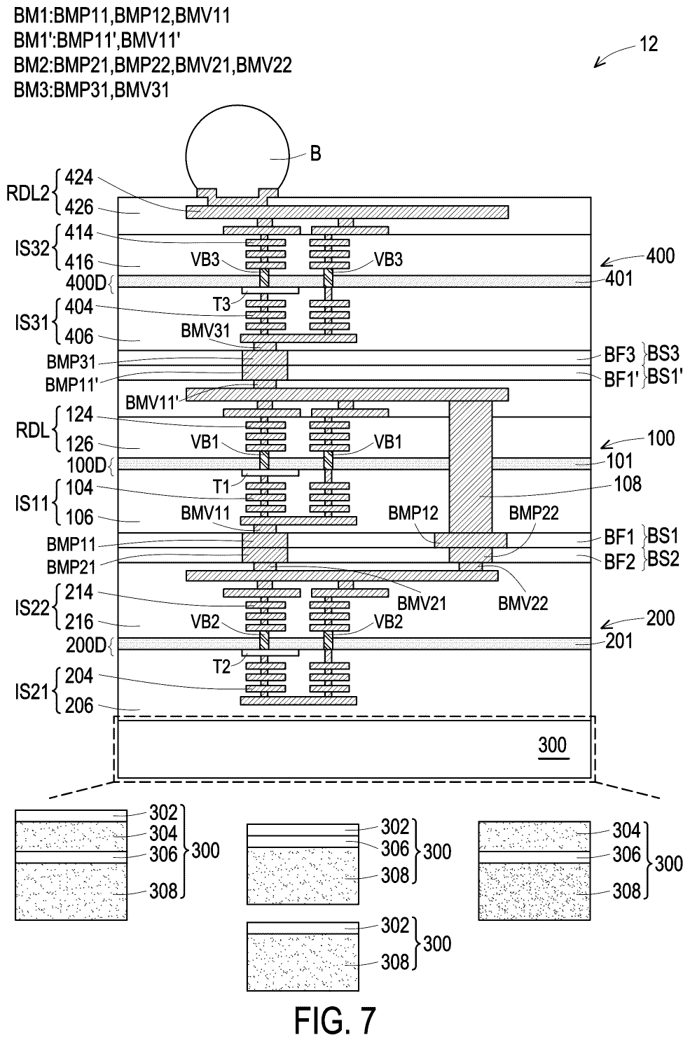

FIG. 7 illustrates a cross-sectional view of an integrated circuit structure in accordance with some embodiments of the present disclosure.

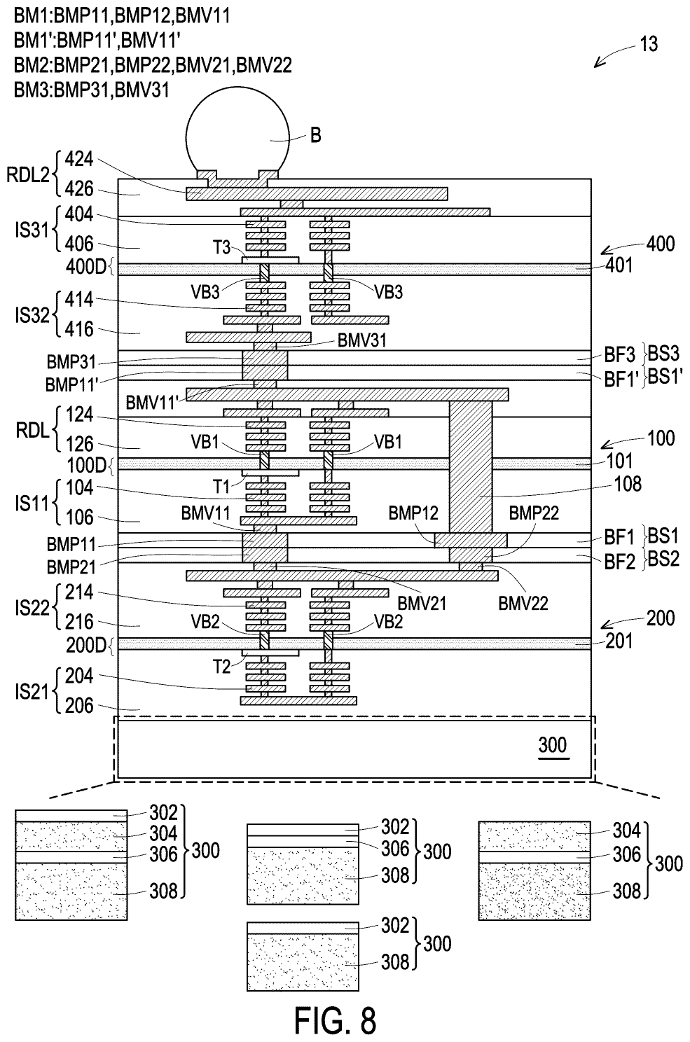

FIG. 8 illustrates a cross-sectional view of an integrated circuit structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

The present disclosure is directed to integrated circuit structures and forming methods thereof. The integrated circuit structure of the disclosure includes multiple dies vertically stacked, and interconnect structure(s) or power delivery network(s) may be placed on a single side or both sides of each die for routing flexibility. However, hot spots may generated in a die with both front-side and backside interconnect structures. In the disclosure, a heat dissipation structure is in direct contact with one die of the integrated circuit structure of the disclosure, so as to lower the device temperature and improve the device performance.

FIG. 1A to FIG. 1I illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 1A to FIG. 1I are described in relation to a method, it is appreciated that the structures disclosed in FIG. 1A to FIG. 1I are not limited to such a method, but instead may stand alone as structures independent of the method.

Referring to FIG. 1A, a die 100 is placed on a carrier C0. In some embodiments, the carrier C0 includes a silicon carrier or a suitable carrier. In some embodiments, the die 100 is attached to the carrier C0 through an adhesive layer AL0. The adhesive layer AL0 may include an oxide layer, a die attach tape (DAF) or a suitable adhesive.

The die 100 may be any suitable type of die, such as a logic die, a memory die, a radio frequency die, an analog chip, a sensor chip, a power management die, a voltage regulator chip, a micro-electro-mechanical-system (MEMS) die, a system on chip (SoC), a CPU, a GPU, an xPU, or the like. In some embodiments, the die 100 includes a device layer 100D, a front-side interconnect structure IS11 and a backside interconnect structure IS12 on opposite sides of the device layer 100D. In this embodiments, the front-side interconnect structure IS11 of the die 100 is in direct contact with the adhesive layer AL0.

The device layer 100D may include a substrate and a transistor disposed on/at the substrate. The substrate may include elementary semiconductor such as silicon, germanium and/or a compound semiconductor such as silicon germanium, silicon carbide, gallium arsenic, indium arsenide, gallium nitride or indium phosphide. The transistor may include a fin field effect transistor (FinFET), a nanostructure FET (nano-FET) (e.g., a nanosheet transistor, a nanowire transistor or a gate-all-around transistor), a planar FET, the like, or a combination thereof. In some embodiments, the device layer 100D further includes metal vias penetrating through the substrate and configured to electrically connected to the front-side and backside interconnect structures on opposite sides of the device layer 100D.

The front-side interconnect structure IS11 is disposed on the front side (or called “active side” in some examples) of the device layer 100D. The front-side interconnect structure IS11 may include metal features 104 embedded by dielectric layers 106 and electrically connected to each other. The dielectric layers 106 may include etch stop layers and inter-metal dielectric (IMD) layers with different materials. The etch stop layers may include silicon nitride, silicon oxynitride, silicon nitride with oxygen (O) or carbon (C) elements, metal oxide such as Al₂O₃, the like, or a combination thereof. The IMD layers may include silicon oxide, silicon oxynitride, silicon nitride, a low-k material having a dielectric constant less than 3.5, the like, or a combination thereof. The metal features 104 include metal lines, metal vias and/or metal pads. The metal vias are formed between and in direct contact with two metal lines. The metal features 104 may include Cu, Al, Ti, Ta, W, Ru, Co, Ni, the like, or a combination thereof. In some embodiments, a metal liner may be disposed between each metal feature 104 and the adjacent dielectric layer 106. In some embodiments, the metal liner includes a seed layer and/or a barrier layer. The seed layer may include Ti/Cu. The barrier layer may include Ta, TaN, Ti, TiN, CoW or a combination thereof. The front-side interconnect structure IS11 is referred to as a “back end of line (BEOL) structure” or “front-side power delivery network (PDN)” in some examples. In an embodiment, the front-side interconnect structure IS11 has a thickness of about 0.5 μm to about 2 μm.

The backside interconnect structure IS12 is disposed on the back side (or called “non-active side” in some examples)) of the device layer 100D. The backside interconnect structure IS12 may include metal features 114 embedded by dielectric layers 116 and electrically connected to each other. The dielectric layers 116 may include etch stop layers and inter-metal dielectric (IMD) layers with different materials. The etch stop layers may include silicon nitride, silicon oxynitride, silicon nitride with oxygen (O) or carbon (C) elements, metal oxide such as Al₂O₃, the like, or a combination thereof. The IMD layers may include silicon oxide, silicon oxynitride, silicon nitride, a low-k material having a dielectric constant less than 3.5, the like, or a combination thereof. The metal features 114 include metal lines, metal vias and/or metal pads. The metal vias are formed between and in direct contact with two metal lines. The metal features 114 may include Cu, Al, Ti, Ta, W, Ru, Co, Ni, the like, or a combination thereof. In some embodiments, a metal liner may be disposed between each metal feature 114 and the adjacent dielectric layer 116. In some embodiments, the metal liner includes a seed layer and/or a barrier layer. The seed layer may include Ti/Cu. The barrier layer may include Ta, TaN, Ti, TiN, CoW or a combination thereof. In some embodiments, the backside interconnect structure IS12 is electrically connected to the front-side interconnect structure IS11 through the device layer 100D. The backside interconnect structure IS12 is referred to as a “super power rail (SPR) structure” or “backside power delivery network (PDN)” in some examples. In an embodiment, the backside interconnect structure IS12 has a thickness of about 0.5 μm to about 2 μm. The die 100 with front-side and backside interconnect structures is referred to a “SPR die” in some examples.

In some embodiments, the die 100 further includes at least one deep through via 108 penetrating through the backside interconnect structure IS12, the device layer 100D and the front-side interconnect structure IS11. In some embodiments, multiple deep through vias 108 are included in the die 100, some of the deep through vias 108 are active through vias (e.g., functional vias) for providing electric connection between electric components, and some of the deep through vias 108 are dummy through vias (e.g., floating vias) for improving bonding performance or enhancing the structure stiffness. The deep through via 108 may include a metal feature and a metal liner surrounding the metal layer. The metal feature may include Cu, Al, Ti, Ta, W, Ru, Co, Ni, the like, or a combination thereof. The metal liner may include a seed layer and/or a barrier layer. The seed layer may include Ti/Cu. The barrier layer may include Ta, TaN, Ti, TiN, CoW or a combination thereof. In some embodiments, an insulating liner layer may be disposed between the deep through via 108 and the adjacent substrate and the dielectric layers. The insulating liner may include silicon oxide, silicon nitride or the like.

Referring to FIG. 1B, the die 100 is placed on the carrier C1. In some embodiments, the carrier C1 includes a silicon carrier or a suitable carrier. In some embodiments, the die 100 is attached to the carrier C1 through an adhesive layer AL1. The adhesive layer AL1 may include an oxide layer, a die attach tape (DAF) or a suitable adhesive. In this embodiments, the backside interconnect structure IS12 of the die 100 is in direct contact with the adhesive layer AL1.

Referring to FIG. 1C, the carrier C0 is removed from the front-side interconnect structure IS11 of the die 100. In some embodiments, the adhesive layer AL0 is further removed to expose the front-side interconnect structure IS11 of the die 100. In some embodiments, the removing process includes an etching process or a suitable process.

Referring to FIG. 1D, a bonding structure BS1 is formed over and electrically connected to the front-side interconnect structure IS11 of the die 100. In some embodiments, the bonding structure BS1 includes bonding metal features BM1 embedded by a bonding film BF1. Each bonding metal feature BM1 includes a metal pad, a metal via or a combination thereof. The bonding metal features BM1 may include Cu, Al, Ti, Ta, W, Ru, Co, Ni, the like, or a combination thereof. In some embodiments, a metal liner may be disposed between each bonding metal feature BM1 and the bonding film BF1. In some embodiments, the metal liner includes a seed layer and/or a barrier layer. The seed layer may include Ti/Cu. The barrier layer may include Ta, TaN, Ti, TiN, CoW or a combination thereof. The bonding film BF1 may include silicon oxide, silicon oxynitride, silicon nitride, the like, or a combination thereof. In some embodiments, the bonding structure BS1 is regarded as part of the die 100.

Referring to FIG. 1E, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure. For example, the heat dissipation layer 302 may have a two-layer (including, for example, SiO₂ and AlN; AlN and Al₂O₃; etc.) or a three-layer structure.

The die 200 may be any suitable type of die, such as a logic die, a memory die, a radio frequency die, an analog chip, a sensor chip, a power management die, a voltage regulator chip, a micro-electro-mechanical-system (MEMS) die, a system on chip (SoC), a CPU, a GPU, an xPU, or the like. In some embodiments, the die 200 includes a device layer 200D, a front-side interconnect structure IS21 and a backside interconnect structure IS22 on opposite sides of the device layer 200D. In this embodiments, the front-side interconnect structure IS21 of the die 200 is in direct contact with the heat dissipation layer 302.

The device layer 200D may include a substrate and a transistor disposed on/at the substrate. The substrate may include elementary semiconductor such as silicon, germanium and/or a compound semiconductor such as silicon germanium, silicon carbide, gallium arsenic, indium arsenide, gallium nitride or indium phosphide. The transistor may include a fin field effect transistor (FinFET), a nanostructure FET (nano-FET) (e.g., a nanosheet transistor, a nanowire transistor or a gate-all-around transistor), a planar FET, the like, or a combination thereof. In some embodiments, the device layer 200D further includes metal vias penetrating through the substrate and configured to electrically connected to the front-side and backside interconnect structures on opposite sides of the device layer 200D.

The front-side interconnect structure IS21 is disposed on the front side (or called “active side” in some examples) of the device layer 200D. The interconnect structure IS11 may include metal features 204 embedded by dielectric layers 206 and electrically connected to each other. The dielectric layers 206 may include etch stop layers and inter-metal dielectric (IMD) layers with different materials. The etch stop layers may include silicon nitride, silicon oxynitride, silicon nitride with oxygen (O) or carbon (C) elements, metal oxide such as Al₂O₃, the like, or a combination thereof. The IMD layers may include silicon oxide, silicon oxynitride, silicon nitride, a low-k material having a dielectric constant less than 3.5, the like, or a combination thereof. The metal features 204 include metal lines, metal vias and/or metal pads. The metal vias are formed between and in direct contact with two metal lines. The metal features 204 may include Cu, Al, Ti, Ta, W, Ru, Co, Ni, the like, or a combination thereof. In some embodiments, a metal liner may be disposed between each metal feature 204 and the adjacent dielectric layer 206. In some embodiments, the metal liner includes a seed layer and/or a barrier layer. The seed layer may include Ti/Cu. The barrier layer may include Ta, TaN, Ti, TiN, CoW or a combination thereof. The front-side interconnect structure IS21 is referred to as a “back end of line (BEOL) structure” or “front-side power delivery network (PDN)” in some examples. In an embodiment, the front-side interconnect structure IS21 has a thickness of about 0.5 μm to about 2 μm.

The backside interconnect structure IS22 is disposed on the back side (or called “non-active side” in some examples)) of the device layer 200D. The backside interconnect structure IS22 may include metal features 214 embedded by dielectric layers 216 and electrically connected to each other. The dielectric layers 216 may include etch stop layers and inter-metal dielectric (IMD) layers with different materials. The etch stop layers may include silicon nitride, silicon oxynitride, silicon nitride with oxygen (O) or carbon (C) elements, metal oxide such as Al₂O₃, the like, or a combination thereof. The IMD layers may include silicon oxide, silicon oxynitride, silicon nitride, a low-k material having a dielectric constant less than 3.5, the like, or a combination thereof. The metal features 214 include metal lines, metal vias and/or metal pads. The metal vias are formed between and in direct contact with two metal lines. The metal features 214 may include Cu, Al, Ti, Ta, W, Ru, Co, Ni, the like, or a combination thereof. In some embodiments, a metal liner may be disposed between each metal feature 214 and the adjacent dielectric layer 216. In some embodiments, the metal liner includes a seed layer and/or a barrier layer. The seed layer may include Ti/Cu. The barrier layer may include Ta, TaN, Ti, TiN, CoW or a combination thereof. In some embodiments, the backside interconnect structure IS22 is electrically connected to the front-side interconnect structure IS21 through the device layer 100D. The backside interconnect structure IS22 is referred to as a “super power rail (SPR) structure” or “backside power delivery network (PDN)” in some examples. In an embodiment, the backside interconnect structure IS22 has a thickness of about 0.5 μm to about 2 μm. The die 200 with front-side and backside interconnect structures is referred to a “SPR die” in some examples.

Still referring to FIG. 1E, a bonding structure BS2 is formed over and electrically connected to the backside interconnect structure IS22. In some embodiments, the bonding structure BS2 includes bonding metal features BM2 embedded by a bonding film BF2. Each bonding metal feature BM2 includes a metal pad, a metal via or a combination thereof. The bonding metal features BM2 may include Cu, Al, Ti, Ta, W, Ru, Co, Ni, the like, or a combination thereof. In some embodiments, a metal liner may be disposed between each bonding metal feature BM2 and the bonding film BF2. In some embodiments, the metal liner includes a seed layer and/or a barrier layer. The seed layer may include Ti/Cu. The barrier layer may include Ta, TaN, Ti, TiN, CoW or a combination thereof. The bonding film BF2 may include silicon oxide, silicon oxynitride, silicon nitride, the like, or a combination thereof. In some embodiments, the bonding structure BS2 is regarded as part of the die 200.

Referring to FIG. 1F, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 1G, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. For example, the heat dissipation layer 302 may have a two-layer (including, for example, SiO₂ and AlN; AlN and Al₂O₃; etc.) or a three-layer structure.

In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Referring to FIG. 1H, the structure of FIG. 1G is turned over and the carrier C1 is then removed from the backside interconnect structure IS12 of the die 100. In some embodiments, the adhesive layer AL1 is further removed to expose the backside interconnect structure IS12 of the die 100. In some embodiments, the removing process includes an etching process or a suitable process.

Referring to FIG. 1I, a redistribution layer structure RDL is formed over and electrically connected to the backside interconnect structure IS12 of the die 100. The redistribution layer structure RDL may include metal features 124 embedded by dielectric layers 126 and electrically connected to each other. The dielectric layers 126 may include etch stop layers and inter-metal dielectric (IMD) layers with different materials. The etch stop layers may include silicon nitride, silicon oxynitride, silicon nitride with oxygen (O) or carbon (C) elements, metal oxide such as Al₂O₃, the like, or a combination thereof. The IMD layers may include silicon oxide, silicon oxynitride, silicon nitride, a low-k material having a dielectric constant less than 3.5, the like, or a combination thereof. The metal features 124 include metal lines, metal vias and/or metal pads. The metal vias are formed between and in direct contact with two metal lines. The metal features 124 may include Cu, Al, Ti, Ta, W, Ru, Co, Ni, the like, or a combination thereof. In some embodiments, a metal liner may be disposed between each metal feature 124 and the adjacent dielectric layer 126. In some embodiments, the metal liner includes a seed layer and/or a barrier layer. The seed layer may include Ti/Cu. The barrier layer may include Ta, TaN, Ti, TiN, CoW or a combination thereof. The redistribution layer structure RDL may be referred to as a “post-interconnect structure” in some examples. In an embodiment, the redistribution layer structure RDL has a thickness of about 0.5 μm to about 2 μm. In some embodiments, the sidewall of the redistribution layer structure RDL is flush with the sidewall of the front-side interconnect structure IS11 or the sidewall of the backside interconnect structure IS12. In some embodiments, the redistribution layer structure RDL is regarded as part of the die 100.

Thereafter, conductive terminals or bumps B are formed over and electrically connected to the redistribution layer structure RDL. In some embodiments, the bumps B include solder bumps, and/or may include metal pillars (e.g., copper pillars), solder caps formed on metal pillars, and/or the like. The bumps B may be formed by a suitable process such as evaporation, electroplating, ball drop, or screen printing. An integrated circuit structure 10 of some embodiments is thus completed.

FIG. 1J is another integrated circuit structure formed by the above method described in FIG. 1A to FIG. 1I, in which more details are shown for illustration. Herein, similar elements are indicated by similar reference numerals, so the materials and forming methods of similar elements may refer to those described above, and the details are not iterated herein.

Referring to FIG. 1J, the integrated circuit structure 11 includes a die 100 and a die 200 vertically stacked on one another, and a heat dissipation structure 300 in direct contact with the die 200.

The die 100 includes a device layer 100D, a front-side interconnect structure IS11 and a backside interconnect structure IS12. The device layer 100D includes a substrate 101 and a transistor T1. The transistor T1 may include a fin field effect transistor (FinFET), a nanostructure FET (nano-FET) (e.g., a nanosheet transistor, a nanowire transistor or a gate-all-around transistor), a planar FET, the like, or a combination thereof. The substrate 101 may have a thickness of about 0.01 μm to 0.1 μm. The substrate 101 has a front side (or called “active side”) and a backside (or called “non-active side”) opposite to the front side. The front-side interconnect structure IS11 is disposed on the front side of the device layer 100D and electrically connected to the device layer 100D. The backside interconnect structure IS12 is disposed on the back side of the device layer 100D and electrically connected to the device layer 100D. In some embodiments, the front-side interconnect structure IS11 is electrically connected to the backside interconnect structure IS12 through metal vias VB1 that penetrate through the thin substrate 101 of about 0.01 μm to 0.1 μm thick. The metal vias VB1 may have a width of about 0.1 μm to about 0.5 μm. The width of the metal vias VB1 is the same as or slightly greater than the width of the adjacent metal vias of the interconnect structures.

The die 100 further includes at least one deep through via 108 that penetrates the backside interconnect structure IS12, the device layer 100D and the front-side interconnect structure IS11.

The die 100 further includes a bonding structure BS1 disposed on and electrically connected to the front-side interconnect structure IS11 and including bonding metal features BM1 embedded in a boding layer BF1. In this embodiments, the bonding metal features BM1 include a bonding metal pad BMP11 and a bonding metal via BMV11 in direct contact with each other, and the bonding metal via BMV11 is in direct contact with a top metal feature of the front-side interconnect structure IS11. In this embodiments, the bonding metal features BM1 include a bonding metal pad BMP12 in direct contact with the deep through via 108.

The die 200 includes a device layer 200D, a front-side interconnect structure IS21 and a backside interconnect structure IS22. The device layer 200D includes a substrate 201 and a transistor T2. The substrate 201 may have a thickness of about 0.01 μm to 0.1 μm. The substrate 201 has a front side (or called “active side”) and a backside (or called “non-active side”) opposite to the front side. The device layer 200D is disposed on the front side of the substrate 201. The transistor T2 may include a fin field effect transistor (FinFET), a nanostructure FET (nano-FET) (e.g., a nanosheet transistor, a nanowire transistor or a gate-all-around transistor), a planar FET, the like, or a combination thereof. The front-side interconnect structure IS21 is disposed on the front side of the device layer 200D and electrically connected to the device layer 200D. The backside interconnect structure IS22 is disposed on the back side of the device layer 200D and electrically connected to the device layer 200D. In some embodiments, the front-side interconnect structure IS21 is electrically connected to the backside interconnect structure IS22 through metal vias VB2 that penetrate through the thin substrate 201 of about 0.01 μm to 0.1 μm thick. The metal vias VB2 may have a width of about 0.1 μm to about 0.5 μm. The width of the metal vias VB2 is the same as or slightly greater than the width of the adjacent metal vias of the interconnect structures.

The die 200 further includes a bonding structure BS2 disposed on and electrically connected to the backside interconnect structure IS22 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the backside interconnect structure IS22. In this embodiments, the bonding metal features BM2 include a bonding metal pad BMP22 and a bonding metal via BMV22 in direct contact with each other, and the bonding metal via BMV22 is in direct contact with a top metal feature of the backside interconnect structure IS22.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the front-side interconnect structure IS21 of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 1J. The material of the heat dissipation layer 302 may be different from material of the heat dissipation layer 306 for improving the heat dissipation performance.

In some embodiments, a redistribution layer structure RDL is disposed over and electrically connected to the backside interconnect structure IS12 of the die 100. In some embodiments, bumps B are disposed over and electrically connected to under bump metallization (UBM) pads of the redistribution layer structure RDL.

FIG. 2A to FIG. 2E illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 2A to FIG. 2E are described in relation to a method, it is appreciated that the structures disclosed in FIG. 2A to FIG. 2E are not limited to such a method, but instead may stand alone as structures independent of the method. Herein, similar elements are indicated by similar reference numerals, so the materials and forming methods of similar elements may refer to those described above, and the details are not iterated herein.

Referring to FIG. 2A, a die 100 is placed on a carrier C1 through an adhesion layer AL1. In some embodiments, the die 100 includes a device layer 100D, a front-side interconnect structure IS11 and a backside interconnect structure IS12 on opposite sides of the device layer 100D. In this embodiments, the backside interconnect structure IS12 of the die 100 is in direct contact with the adhesive layer AL1.

Referring to FIG. 2B, a bonding structure BS1 is formed over and electrically connected to the front-side interconnect structure IS11 of the die 100. In some embodiments, the bonding structure BS1 includes bonding metal features BM1 embedded by a bonding film BF1.

Referring to FIG. 2C, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the die 200 includes a device layer 200D and a front-side interconnect structure IS21 on the front side of the device layer 200D. In this embodiments, the device layer 200D of the die 200 is in direct contact with the heat dissipation layer 302.

In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure.

Still referring to FIG. 2C, a bonding structure BS2 is formed over and electrically connected to the front-side interconnect structure IS21. In some embodiments, the bonding structure BS2 includes bonding metal features BM2 embedded by a bonding film BF2.

Referring to FIG. 2D, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 2E, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Thereafter, the structure is turned over and the carrier C1 is then removed from the backside interconnect structure IS12 of the die 100. In some embodiments, the adhesive layer AL1 is further removed to expose the backside interconnect structure IS12 of the die 100. In some embodiments, the removing process includes an etching process or a suitable process.

Afterwards, a redistribution layer structure RDL is formed over and electrically connected to the backside interconnect structure IS12 of the die 100. The redistribution layer structure RDL may include metal features 124 embedded by dielectric layers 126 and electrically connected to each other.

Thereafter, conductive terminals or bumps B are formed over and electrically connected to the redistribution layer structure RDL. An integrated circuit structure 20 of some embodiments is thus completed.

FIG. 2F is another integrated circuit structure formed by the above method described in FIG. 2A to FIG. 2E, in which more details are shown for illustration. Herein, similar elements are indicated by similar reference numerals, so the materials and forming methods of similar elements may refer to those described above, and the details are not iterated herein.

Referring to FIG. 2F, the integrated circuit structure 21 includes a die 100 and a die 200 vertically stacked on one another, and a heat dissipation structure 300 in direct contact with the die 200.

The die 100 includes a device layer 100D, a front-side interconnect structure IS11 and a backside interconnect structure IS12. The device layer 100D includes a substrate 101 and a transistor T1. The substrate 101 has a thickness of about 0.01 μm to 0.1 μm. The front-side interconnect structure IS11 is disposed on the front side of the device layer 100D and electrically connected to the device layer 100D. The backside interconnect structure IS12 is disposed on the back side of the device layer 100D and electrically connected to the device layer 100D. In some embodiments, the front-side interconnect structure IS11 is electrically connected to the backside interconnect structure IS12 through metal vias VB1 that penetrate through the thin substrate 101 of about 0.01 μm to 0.1 μm thick. The metal vias VB1 may have a width of about 0.1 μm to about 0.5 μm. The width of the metal vias VB1 is the same as or slightly greater than the width of the adjacent metal vias of the interconnect structures.

The die 100 further includes a bonding structure BS1 disposed on and electrically connected to the front-side interconnect structure IS11 and including bonding metal features BM1 embedded in a boding layer BF1. In this embodiments, the bonding metal features BM1 include a bonding metal pad BMP11 and a bonding metal via BMV11 in direct contact with each other, and the bonding metal via BMV11 is in direct contact with a top metal feature of the front-side interconnect structure IS11. In this embodiments, the bonding metal features BM1 include a bonding metal pad BMP12. The bonding metal pad BMP12 may be a dummy bonding pad for improving the bonding performance.

The die 200 includes a device layer 200D and a front-side interconnect structure IS21. The device layer 200D includes a substrate 201 and a transistor T2. The substrate 201 may have a thickness of about 0.1 μm to about 1000 μm, such as about 600 μm to 800 μm. The front-side interconnect structure IS21 is disposed on the front side of the device layer 200D and electrically connected to the device layer 200D.

The die 200 further includes a bonding structure BS2 disposed on and electrically connected to the front-side interconnect structure IS21 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the front-side interconnect structure IS21. In this embodiments, the bonding metal features BM2 include a bonding metal pad BMP22. The bonding metal pad BMP22 may be a dummy bonding pad for improving the bonding performance.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the device layer 200D of the die 200. Specifically, the heat dissipation structure 300 is in direct contact with the substrate 201 of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 2F. The material of the heat dissipation layer 302 may be different from material of the heat dissipation layer 306 for improving the heat dissipation performance.

In some embodiments, a redistribution layer structure RDL is disposed over and electrically connected to the backside interconnect structure IS12 of the die 100. In some embodiments, bumps B are disposed over and electrically connected to under bump metallization (UBM) pads of the redistribution layer structure RDL.

FIG. 3A to FIG. 3E illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 3A to FIG. 3E are described in relation to a method, it is appreciated that the structures disclosed in FIG. 3A to FIG. 3E are not limited to such a method, but instead may stand alone as structures independent of the method. Herein, similar elements are indicated by similar reference numerals, so the materials and forming methods of similar elements may refer to those described above, and the details are not iterated herein.

Referring to FIG. 3A, a die 100 is placed on a carrier C1 through an adhesion layer AL1. In some embodiments, the die 100 includes a device layer 100D and a front-side interconnect structure IS11 on the front side of the device layer 100D. The die 100 further include at least one deep through via 108 penetrating through the device layer 100D and the front-side interconnect structure IS11. In this embodiments, the device layer 100D of the die 100 is in direct contact with the adhesive layer AL1.

Referring to FIG. 3B, a bonding structure BS1 is formed over and electrically connected to the front-side interconnect structure IS11 of the die 100. In some embodiments, the bonding structure BS1 includes bonding metal features BM1 embedded by a bonding film BF1.

Referring to FIG. 3C, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the die 200 includes a device layer 200D, a front-side interconnect structure IS21 on the front side of the device layer 200D, and a backside interconnect structure IS22 on the back side of the device layer 200D. In this embodiments, the front-side interconnect structure IS21 of the die 200 is in direct contact with the heat dissipation layer 302.

In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure.

Still referring to FIG. 3C, a bonding structure BS2 is formed over and electrically connected to the backside interconnect structure IS22. In some embodiments, the bonding structure BS2 includes bonding metal features BM2 embedded by a bonding film BF2.

Referring to FIG. 3D, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 3E, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Thereafter, the structure is turned over and the carrier C1 is then removed from the device layer 100D of the die 100. In some embodiments, the adhesive layer AL1 is further removed to expose the device layer 100D and the deep through via 108 of the die 100. In some embodiments, the removing process includes an etching process or a suitable process.

Afterwards, a redistribution layer structure RDL is formed over and electrically connected to the device layer 100D of the die 100. The redistribution layer structure RDL may include metal features 124 embedded by dielectric layers 126 and electrically connected to each other.

Thereafter, conductive terminals or bumps B are formed over and electrically connected to the redistribution layer structure RDL. An integrated circuit structure 30 of some embodiments is thus completed.

FIG. 3F is another integrated circuit structure formed by the above method described in FIG. 3A to FIG. 3E, in which more details are shown for illustration. Herein, similar elements are indicated by similar reference numerals, so the materials and forming methods of similar elements may refer to those described above, and the details are not iterated herein.

Referring to FIG. 3F, the integrated circuit structure 31 includes a die 100 and a die 200 vertically stacked on one another, and a heat dissipation structure 300 in direct contact with the die 200.

The die 100 includes a device layer 100D and a front-side interconnect structure IS11. The device layer 100D includes a substrate 101 and a transistor T1. The substrate 101 may have a thickness of about 0.1 μm to about 1000 μm, such as about 600 μm to 800 μm. The front-side interconnect structure IS11 is disposed on the front side of the device layer 100D and electrically connected to the device layer 100D. In some embodiments, the front-side interconnect structure IS11 of the die 100 is electrically connected to the die 200 through at least one deep through via 108.

The die 100 further includes a bonding structure BS1 disposed on and electrically connected to the device layer 100D and including bonding metal features BM1 embedded in a boding layer BF1. An insulating layer 105 is further disposed between the substrate 101 and the bonding structure BS1. The insulating layer 105 may include silicon oxide, silicon oxynitride or the like. In this embodiments, the bonding metal features BM1 include a bonding metal pad BMP11 in direct contact with one of the deep through vias 108. In this embodiments, the bonding metal features BM1 include a bonding metal pad BMP12 in direct contact with another of the deep through vias 108.

The die 200 includes a device layer 200D, a front-side interconnect structure IS21 and a backside interconnect structure IS22. The device layer 200D includes a substrate 201 and a transistor T2. The substrate 201 has a thickness of about 0.01 μm to 0.1 μm. The front-side interconnect structure IS21 is disposed on the front side of the device layer 200D and electrically connected to the device layer 200D. The backside interconnect structure IS22 is disposed on the back side of the device layer 200D and electrically connected to the device layer 200D. In some embodiments, the front-side interconnect structure IS22 is electrically connected to the backside interconnect structure IS22 through metal vias VB2 that penetrate through the thin substrate 201 of about 0.01 μm to 0.1 μm thick. The metal vias VB2 may have a width of about 0.1 μm to about 0.5 μm. The width of the metal vias VB2 is the same as or slightly greater than the width of the adjacent metal vias of the interconnect structures.

The die 200 further includes a bonding structure BS2 disposed on and electrically connected to the backside interconnect structure IS22 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the backside interconnect structure IS22. In this embodiments, the bonding metal features BM2 include a bonding metal pad BMP22 and a bonding metal via BMV22 in direct contact with each other, and the bonding metal via BMV22 is in direct contact with a top metal feature of the backside interconnect structure IS22.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the front-side interconnect structure IS21 of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 3F. The material of the heat dissipation layer 302 may be different from material of the heat dissipation layer 306 for improving the heat dissipation performance.

In some embodiments, a redistribution layer structure RDL is disposed over and electrically connected to the front-side interconnect structure IS11 of the die 100. In some embodiments, bumps B are disposed over and electrically connected to under bump metallization (UBM) pads of the redistribution layer structure RDL.

FIG. 4A to FIG. 4E illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 4A to FIG. 4E are described in relation to a method, it is appreciated that the structures disclosed in FIG. 4A to FIG. 4E are not limited to such a method, but instead may stand alone as structures independent of the method. Herein, similar elements are indicated by similar reference numerals, so the materials and forming methods of similar elements may refer to those described above, and the details are not iterated herein.

Referring to FIG. 4A, a die 100 is placed on a carrier C1 through an adhesion layer AL1. In some embodiments, the die 100 includes a device layer 100D, a front-side interconnect structure IS11 and a backside interconnect structure IS12 on opposite sides of the device layer 100D. In this embodiments, the front-side interconnect structure IS11 of the die 100 is in direct contact with the adhesive layer AL1.

The die 100 further includes at least one deep through via 108 that penetrates the backside interconnect structure IS12, the device layer 100D and the front-side interconnect structure IS11.

Referring to FIG. 4B, a bonding structure BS1 is formed over and electrically connected to the backside interconnect structure IS12 of the die 100. In some embodiments, the bonding structure BS1 includes bonding metal features BM1 embedded by a bonding film BF1.

Referring to FIG. 4C, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the die 200 includes a device layer 200D, a front-side interconnect structure IS21 and a backside interconnect structure IS22. The front-side interconnect structure IS21 is disposed on the front side of the device layer 200D. The backside interconnect structure IS22 is disposed on the back side of the device layer 200D. In this embodiments, the front-side interconnect structure IS21 of the die 200 is in direct contact with the heat dissipation layer 302.

In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure.

Still referring to FIG. 4C, a bonding structure BS2 is formed over and electrically connected to the backside interconnect structure IS22. In some embodiments, the bonding structure BS2 includes bonding metal features BM2 embedded by a bonding film BF2.

Referring to FIG. 4D, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 4E, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Thereafter, the structure is turned over and the carrier C1 is then removed from the front-side interconnect structure IS11 of the die 100. In some embodiments, the adhesive layer AL1 is further removed to expose the front-side interconnect structure IS11 of the die 100. In some embodiments, the removing process includes an etching process or a suitable process.

Afterwards, a redistribution layer structure RDL is formed over and electrically connected to the front-side interconnect structure IS11 of the die 100. The redistribution layer structure RDL may include metal features 124 embedded by dielectric layers 126 and electrically connected to each other.

Thereafter, conductive terminals or bumps B are formed over and electrically connected to the redistribution layer structure RDL. An integrated circuit structure 30 of some embodiments is thus completed.

FIG. 4F is another integrated circuit structure formed by the above method described in FIG. 4A to FIG. 4E, in which more details are shown for illustration. Herein, similar elements are indicated by similar reference numerals, so the materials and forming methods of similar elements may refer to those described above, and the details are not iterated herein.

Referring to FIG. 4F, the integrated circuit structure 41 includes a die 100 and a die 200 vertically stacked on one another, and a heat dissipation structure 300 in direct contact with the die 200.

The die 100 includes a device layer 100D, a front-side interconnect structure IS11 and a backside interconnect structure IS12. The device layer 100D includes a substrate 101 and a transistor T1. The substrate 101 has a thickness of about 0.01 μm to 0.1 μm. The front-side interconnect structure IS11 is disposed on the front side of the device layer 100D and electrically connected to the device layer 100D. The backside interconnect structure IS12 is disposed on the back side of the device layer 100D and electrically connected to the device layer 100D. In some embodiments, the front-side interconnect structure IS11 is electrically connected to the backside interconnect structure IS12 through metal vias VB1 that penetrate through the thin substrate 101 of about 0.01 μm to 0.1 μm thick. The metal vias VB1 may have a width of about 0.1 μm to about 0.5 μm. The width of the metal vias VB1 is the same as or slightly greater than the width of the adjacent metal vias of the interconnect structures.

The die 100 further includes at least one deep through via 108 that penetrates the backside interconnect structure IS12, the device layer 100D and the front-side interconnect structure IS11.

The die 100 further includes a bonding structure BS1 disposed on and electrically connected to the backside interconnect structure IS12 and including bonding metal features BM1 embedded in a boding layer BF1. In this embodiments, the bonding metal features BM1 include a bonding metal pad BMP11 and a bonding metal via BMV11 in direct contact with each other, and the bonding metal via BMV11 is in direct contact with a top metal feature of the backside interconnect structure IS12. In this embodiments, the bonding metal features BM1 include a bonding metal pad BMP12 in direct contact with the deep through via 108.

The die 200 includes a device layer 200D, a front-side interconnect structure IS21 and a backside interconnect structure IS22. The device layer 1200D includes a substrate 201 and a transistor T2. The substrate 201 has a thickness of about 0.01 μm to 0.1 μm. The front-side interconnect structure IS121 is disposed on the front side of the device layer 200D and electrically connected to the device layer 200D. The backside interconnect structure IS22 is disposed on the back side of the device layer 200D and electrically connected to the device layer 200D. In some embodiments, the front-side interconnect structure IS21 is electrically connected to the backside interconnect structure IS22 through metal vias VB2 that penetrate through the thin substrate 201 of about 0.01 μm to 0.1 μm thick. The metal vias VB2 may have a width of about 0.1 μm to about 0.5 μm. The width of the metal vias VB2 is the same as or slightly greater than the width of the adjacent metal vias of the interconnect structures.

The die 200 further includes a bonding structure BS2 disposed on and electrically connected to the backside interconnect structure IS22 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the backside interconnect structure IS22. In this embodiments, the bonding metal features BM2 include a bonding metal pad BMP22 and a bonding metal via BMV22 in direct contact with each other, and the bonding metal via BMV22 is in direct contact with a top metal feature of the backside interconnect structure IS22.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the front-side interconnect structure of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 4F. The material of the heat dissipation layer 302 may be different from material of the heat dissipation layer 306 for improving the heat dissipation performance.

In some embodiments, a redistribution layer structure RDL is disposed over and electrically connected to the front-side interconnect structure IS11 of the die 100. In some embodiments, bumps B are disposed over and electrically connected to under bump metallization (UBM) pads of the redistribution layer structure RDL.

FIG. 5A to FIG. 5E illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 5A to FIG. 5E are described in relation to a method, it is appreciated that the structures disclosed in FIG. 5A to FIG. 5E are not limited to such a method, but instead may stand alone as structures independent of the method. Herein, similar elements are indicated by similar reference numerals, so the materials and forming methods of similar elements may refer to those described above, and the details are not iterated herein.

Referring to FIG. 5A, a die 100 is placed on a carrier C1 through an adhesion layer AL1. In some embodiments, the die 100 includes a device layer 100D, a front-side interconnect structure IS11 and a backside interconnect structure IS12 on opposite sides of the device layer 100D. In this embodiments, the front-side interconnect structure IS11 of the die 100 is in direct contact with the adhesive layer AL1.

Referring to FIG. 5B, a bonding structure BS1 is formed over and electrically connected to the backside interconnect structure IS12 of the die 100. In some embodiments, the bonding structure BS1 includes bonding metal features BM1 embedded by a bonding film BF1.

Referring to FIG. 5C, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the die 200 includes a device layer 200D and a front-side interconnect structure IS21 on the front side of the device layer 200D. In this embodiments, the device layer 200D of the die 200 is in direct contact with the heat dissipation layer 302.

In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure.

Still referring to FIG. 5C, a bonding structure BS2 is formed over and electrically connected to the front-side interconnect structure IS21. In some embodiments, the bonding structure BS2 includes bonding metal features BM2 embedded by a bonding film BF2.

Referring to FIG. 5D, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 5E, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Thereafter, the structure is turned over and the carrier C1 is then removed from the front-side interconnect structure IS11 of the die 100. In some embodiments, the adhesive layer AL1 is further removed to expose the front-side interconnect structure IS11 of the die 100. In some embodiments, the removing process includes an etching process or a suitable process.

Afterwards, a redistribution layer structure RDL is formed over and electrically connected to the front-side interconnect structure IS11 of the die 100. The redistribution layer structure RDL may include metal features 124 embedded by dielectric layers 126 and electrically connected to each other.

Thereafter, conductive terminals or bumps B are formed over and electrically connected to the redistribution layer structure RDL. An integrated circuit structure 20 of some embodiments is thus completed.

FIG. 5F is another integrated circuit structure formed by the above method described in FIG. 5A to FIG. 5E, in which more details are shown for illustration. Herein, similar elements are indicated by similar reference numerals, so the materials and forming methods of similar elements may refer to those described above, and the details are not iterated herein.

Referring to FIG. 5F, the integrated circuit structure 51 includes a die 100 and a die 200 vertically stacked on one another, and a heat dissipation structure 300 in direct contact with the die 200.

The die 100 includes a device layer 100D, a front-side interconnect structure IS11 and a backside interconnect structure IS12. The device layer 100D includes a substrate 101 and a transistor T1. The substrate 101 has a thickness of about 0.01 μm to 0.1 μm. The front-side interconnect structure IS11 is disposed on the front side of the device layer 100D and electrically connected to the device layer 100D. The backside interconnect structure IS12 is disposed on the back side of the device layer 100D and electrically connected to the device layer 100D. In some embodiments, the front-side interconnect structure IS11 is electrically connected to the backside interconnect structure IS12 through metal vias VB1 that penetrate through the thin substrate 101 of about 0.01 μm to 0.1 μm thick. The metal vias VB1 may have a width of about 0.1 μm to about 0.5 μm. The width of the metal vias VB1 is the same as or slightly greater than the width of the adjacent metal vias of the interconnect structures.

The die 100 further includes a bonding structure BS1 disposed on and electrically connected to the backside interconnect structure IS12 and including bonding metal features BM1 embedded in a boding layer BF1. In this embodiments, the bonding metal features BM1 include a bonding metal pad BMP11 and a bonding metal via BMV11 in direct contact with each other, and the bonding metal via BMV11 is in direct contact with a top metal feature of the backside interconnect structure IS12. In this embodiments, the bonding metal features BM1 include a bonding metal pad BMP12. The bonding metal pad BMP12 may be a dummy bonding pad for improving the bonding performance.

The die 200 includes a device layer 200D and a front-side interconnect structure IS21. The device layer 200D includes a substrate 201 and a transistor T2. The substrate 201 may have a thickness of about 0.1 μm to about 1000 μm, such as about 600 μm to 800 μm. The front-side interconnect structure IS21 is disposed on the front side of the device layer 200D and electrically connected to the device layer 200D.

The die 200 further includes a bonding structure BS2 disposed on and electrically connected to the front-side interconnect structure IS21 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the front-side interconnect structure IS21. In this embodiments, the bonding metal features BM2 include a bonding metal pad BMP22. The bonding metal pad BMP22 may be a dummy bonding pad for improving the bonding performance.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the device layer 200D of the die 200. Specifically, the heat dissipation structure 300 is in direct contact with the substrate 201 of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 5F. The material of the heat dissipation layer 302 may be different from material of the heat dissipation layer 306 for improving the heat dissipation performance.

In some embodiments, a redistribution layer structure RDL is disposed over and electrically connected to the front-side interconnect structure IS11 of the die 100. In some embodiments, bumps B are disposed over and electrically connected to under bump metallization (UBM) pads of the redistribution layer structure RDL.

FIG. 6A to FIG. 6E illustrate cross-sectional views of a method of forming an integrated circuit structure in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIG. 6A to FIG. 6E are described in relation to a method, it is appreciated that the structures disclosed in FIG. 6A to FIG. 6E are not limited to such a method, but instead may stand alone as structures independent of the method. Herein, similar elements are indicated by similar reference numerals, so the materials and forming methods of similar elements may refer to those described above, and the details are not iterated herein.

Referring to FIG. 6A, a die 100 is placed on a carrier C1 through an adhesion layer AL1. In some embodiments, the die 100 includes a device layer 100D and a front-side interconnect structure IS11 on the front side of the device layer 100D. The die 100 further include at least one deep through via 108 penetrating through the device layer 100D and the front-side interconnect structure IS11. In this embodiments, the device layer 100D of the die 100 is in direct contact with the adhesive layer AL1.

Referring to FIG. 6B, a bonding structure BS1 is formed over and electrically connected to the front-side interconnect structure IS11 of the die 100. In some embodiments, the bonding structure BS1 includes bonding metal features BM1 embedded by a bonding film BF1.

Referring to FIG. 6C, a die 200 is placed on a heat dissipation carrier 304. In some embodiments, the heat dissipation carrier 304 includes a silicon carrier or a suitable carrier. In some embodiments, the heat dissipation carrier 304 has a thickness of about 5 μm to about 800 μm, such as about 100 μm to about 600 μm. The thick heat dissipation carrier 304 of the disclosure is beneficial for heat dissipation.

In some embodiments, the die 200 is attached to the heat dissipation carrier 304 through a heat dissipation layer 302. In some embodiments, the die 200 includes a device layer 200D, a front-side interconnect structure IS21 on the front side of the device layer 200D, and a backside interconnect structure IS22 on the back side of the device layer 200D. In this embodiments, the front-side interconnect structure IS21 of the die 200 is in direct contact with the heat dissipation layer 302.

In some embodiments, the heat dissipation layer 302 may span the whole size of the die 200. The heat dissipation layer 302 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 302 may include AlN, GaN, ZnO, BN, Al₂O₃, HfO₂, TiO₂ or a combination thereof. Other materials such as SiO₂, SiN, SION, SiC, SiCN, SiCO may be applicable to the heat dissipation layer 302. In some embodiments, the heat dissipation layer 302 has a thickness of about 0.01 μm to about 2.5 μm. The heat dissipation layer 302 of the disclosure may have a single-layer or multi-layer structure.

Still referring to FIG. 6C, a bonding structure BS2 is formed over and electrically connected to the backside interconnect structure IS22. In some embodiments, the bonding structure BS2 includes bonding metal features BM2 embedded by a bonding film BF2.

Referring to FIG. 6D, the die 200 is turned over and then bonded to the die 100. In some embodiments, the die 200 is bonded to the die 100 through a hybrid bonding including a dielectric-to-dielectric bonding and a metal-to-metal bonding. Specifically, the die 200 is bonded to the die 100 through the bonding structure BS2 and the bonding structure BS1, in which the bonding metal features BM2 are bonded to the bonding metal features BM1, and the bonding film BF2 is bonded to the bonding film BF1.

Referring to FIG. 6E, a heat dissipation support 308 is attached to the heat dissipation carrier 304. In some embodiments, the heat dissipation support 308 includes a silicon support or a suitable support. In some embodiments, the heat dissipation support 308 has a thickness of about 500 μm to about 1000 μm, such as about 600 μm to about 800 μm. The thick heat dissipation support 308 of the disclosure is beneficial for heat dissipation.

In some embodiments, the heat dissipation support 308 is attached to the heat dissipation carrier 304 through a heat dissipation layer 306. In some embodiments, the heat dissipation layer 306 may span the whole size of the die 200. The heat dissipation layer 306 is made of a heat spreader material that is thermally conductive and electrically insulating. The thermal conductivity k for the heat spreader materials should be between about 10 and 500 W/m/K (e.g., between about 20 and 450 W/m/K or between about 50 and 400 W/m/K) for absorbing heat dissipation. For example, the heat dissipation layer 306 may include AlN, GaN, ZnO, BN, Al₂O₃, HfO₂, TiO₂ or a combination thereof. Other materials such as SiO₂, SiN, SiON, SiC, SiCN, SiCO may be applicable to the heat dissipation layer 302. In some embodiments, the heat dissipation layer 306 has a thickness of about 0.01 μm to about 2.5 μm. The heat dissipation layer 306 of the disclosure may have a single-layer or multi-layer structure. In some embodiments, the heat dissipation layer 306 and the heat dissipation layer 302 include the same material. However, the disclosure is not limited thereto. In some embodiments, the heat dissipation layer 306 and the heat dissipation layer 302 include different materials. In some embodiments, the heat dissipation layer 302, the heat dissipation carrier 304, the heat dissipation layer 306 and the heat dissipation support 308 collectively constitute a heat dissipation structure 300. The four-layer heat dissipation structure 300 is provided for illustration purposes, and is not construed as limiting the present disclosure. The heat dissipation structure 300 may have a two-layer or three-layer structure as needed. Specifically, at least one of the heat dissipation layer 302, the heat dissipation carrier 304, the heat dissipation layer 306 and the heat dissipation support 308 may be omitted as needed.

Thereafter, the structure is turned over and the carrier C1 is then removed from the device layer 100D of the die 100. In some embodiments, the adhesive layer AL1 is further removed to expose the device layer 100D and the deep through via 108 of the die 100. In some embodiments, the removing process includes an etching process or a suitable process.

Afterwards, a redistribution layer structure RDL is formed over and electrically connected to the device layer 100D of the die 100. The redistribution layer structure RDL may include metal features 124 embedded by dielectric layers 126 and electrically connected to each other.

Thereafter, conductive terminals or bumps B are formed over and electrically connected to the redistribution layer structure RDL. An integrated circuit structure 60 of some embodiments is thus completed.

FIG. 6F is another integrated circuit structure formed by the above method described in FIG. 6A to FIG. 6E, in which more details are shown for illustration. Herein, similar elements are indicated by similar reference numerals, so the materials and forming methods of similar elements may refer to those described above, and the details are not iterated herein.

Referring to FIG. 6F, the integrated circuit structure 61 includes a die 100 and a die 200 vertically stacked on one another, and a heat dissipation structure 300 in direct contact with the die 200.

The die 100 includes a device layer 100D and a front-side interconnect structure IS11. The device layer 100D includes a substrate 101 and a transistor T1. The substrate 101 may have a thickness of about 0.1 μm to about 1000 μm, such as about 600 μm to 800 μm. The front-side interconnect structure IS11 is disposed on the front side of the device layer 100D and electrically connected to the device layer 100D. In some embodiments, the front-side interconnect structure IS11 of the die 100 is electrically connected to the die 200 through at least one deep through via 108 (e.g., left-side deep through via 108). At least one deep through via 108 (e.g., right-side deep through via 108) may be a dummy through via for enhancing the structure stiffness.

The die 100 further includes a bonding structure BS1 disposed on and electrically connected to the front-side interconnect structure IS11 and including bonding metal features BM1 embedded in a boding layer BF1. In this embodiments, the bonding metal features BM1 include a bonding metal pad BMP11 and a bonding metal via BMV11 in direct contact with each other, and the bonding metal via BMV11 is in direct contact with a top metal feature of the front-side interconnect structure IS11. In this embodiments, the bonding metal features BM1 include a bonding metal pad BMP12. The bonding metal pad BMP12 may be a dummy bonding pad for improving the bonding performance.

The die 200 includes a device layer 200D, a front-side interconnect structure IS21 and a backside interconnect structure IS22. The device layer 200D includes a substrate 201 and a transistor T2. The substrate 201 has a thickness of about 0.01 μm to 0.1 μm. The front-side interconnect structure IS21 is disposed on the front side of the device layer 200D and electrically connected to the device layer 200D. The backside interconnect structure IS22 is disposed on the back side of the device layer 200D and electrically connected to the device layer 200D. In some embodiments, the front-side interconnect structure IS22 is electrically connected to the backside interconnect structure IS22 through metal vias VB2 that penetrate through the thin substrate 201 of about 0.01 μm to 0.1 μm thick. The metal vias VB2 may have a width of about 0.1 μm to about 0.5 μm. The width of the metal vias VB2 is the same as or slightly greater than the width of the adjacent metal vias of the interconnect structures.

The die 200 further includes a bonding structure BS2 disposed on and electrically connected to the backside interconnect structure IS22 and including bonding metal features BM2 embedded in a boding layer BF2. In this embodiments, the bonding metal features BM2 include a bonding metal pad BMP21 and a bonding metal via BMV21 in direct contact with each other, and the bonding metal via BMV21 is in direct contact with a top metal feature of the backside interconnect structure IS22. In this embodiments, the bonding metal features BM2 include a bonding metal pad BMP22. The bonding metal pad BMP22 may be a dummy bonding pad for improving the bonding performance.

In this embodiments, the die 100 is vertically stacked on and bonded to the die 200 through the bonding structures BS1 and BS2. Specifically, the bonding metal pad BMP11 is bonded to the bonding metal pad BMP21, the bonding metal BMP12 is bonded to the bonding metal pad BMP22, and the bonding film BF1 and is bonded to the bonding film BF2.

In some embodiments, the heat dissipation structure 300 is in direct contact with the front-side interconnect structure IS21 of the die 200. The heat dissipation structure 300 may have a four-layer structure including a heat dissipation layer 302, a heat dissipation carrier 304, a heat dissipation layer 306 and a heat dissipation support 308. The thicknesses and materials of each layer of the heat dissipation structure 300 have been described above, so the details are not iterated herein. The dissipation structure 300 may have a two-layer structure or a three-layer structure as shown in FIG. 6F. The material of the heat dissipation layer 302 may be different from material of the heat dissipation layer 306 for improving the heat dissipation performance.

In some embodiments, a redistribution layer structure RDL is disposed over and electrically connected to the device layer 100D of the die 100. In some embodiments, bumps B are disposed over and electrically connected to under bump metallization (UBM) pads of the redistribution layer structure RDL.

The above embodiments in which each integrated circuit structure has a two-tier die stack are provided for illustration purposes, and are not construed as limiting the present disclosure. In some embodiments, the integrated circuit structure may have a three-tier die stack or a four-tier die stack as needed.

FIG. 7 illustrates a cross-sectional view of an integrated circuit structure in accordance with some embodiments of the present disclosure. Herein, similar elements are indicated by similar reference numerals, so the materials and forming methods of similar elements may refer to those described above, and the details are not iterated herein.

The integrated circuit structure 12 of FIG. 7 is similar to the integrated circuit structure 11 of FIG. 1J, so the difference between them is described below, and the similarity is not iterated herein. Specifically, the difference between the integrated circuit structure 12 and the integrated circuit structure 11 lies in that one more die 400 is vertically stacked on the integrated circuit structure 11.

As shown in FIG. 7, a bonding structure BS1′ further formed over and electrically connected to the redistribution layer structure RDL. In some embodiments, the bonding structure BS1′ includes bonding metal features BM1′ embedded by a bonding film BF1′. The materials and forming methods of the bonding metal features BM1′ and the boding layer BF1′ are similar to the materials and forming methods of the bonding metal features BM1 and the boding layer BF1, so the details are not iterated herein. In some embodiments, the bonding structure BS1′ is regarded as part of the die 100. In this embodiments, the bonding metal features BM1′ include a bonding metal pad BMP11′ and a bonding metal via BMV11′ in direct contact with each other, and the bonding metal via BMV11′ is in direct contact with a top metal feature of the redistribution layer structure RDL.

Still referring to FIG. 7, a die 400 is provided and bonded to the die 100. The die 400 may be any suitable type of die, such as a logic die, a memory die, a radio frequency die, an analog chip, a sensor chip, a power management die, a voltage regulator chip, a micro-electro-mechanical-system (MEMS) die, a system on chip (SoC), a CPU, a GPU, an xPU, or the like.

The die 400 includes a device layer 400D, a front-side interconnect structure IS31 and a backside interconnect structure IS32. The device layer 400D includes a substrate 401 and a transistor T3. The substrate 401 may include elementary semiconductor such as silicon, germanium and/or a compound semiconductor such as silicon germanium, silicon carbide, gallium arsenic, indium arsenide, gallium nitride or indium phosphide. The substrate 401 has a thickness of about 0.01 μm to 0.1 μm. The transistor T3 may include a fin field effect transistor (FinFET), a nanostructure FET (nano-FET) (e.g., a nanosheet transistor, a nanowire transistor or a gate-all-around transistor), a planar FET, the like, or a combination thereof. The front-side interconnect structure IS31 is disposed on the front side of the device layer 400D and electrically connected to the device layer 400D. The front-side interconnect structure IS31 may include metal features 404 embedded by dielectric layers 406 and electrically connected to each other. The backside interconnect structure IS32 is disposed on the back side of the device layer 400D and electrically connected to the device layer 400D. The backside interconnect structure IS32 may include metal features 414 embedded by dielectric layers 416 and electrically connected to each other. In some embodiments, the front-side interconnect structure IS31 is electrically connected to the backside interconnect structure IS32 through metal vias VB3 that penetrate through the thin substrate 401 of about 0.01 μm to 0.1 μm thick. The metal vias VB3 may have a width of about 0.1 μm to about 0.5 μm. The width of the metal vias VB3 is the same as or slightly greater than the width of the adjacent metal vias of the interconnect structures. In this embodiments, the front-side interconnect structure IS31 of the die 400 faces the underlying die 100. The materials and forming methods of the device layer 400D, the front-side interconnect structure IS31, the backside interconnect structure IS32 and the metal vias VB3 are similar to the materials and forming methods of the device layer 100D, the front-side interconnect structure IS11, the backside interconnect structure IS12 and the metal vias VB1, so the details are not iterated herein.

The die 400 further includes a bonding structure BS3 disposed on and electrically connected to the front-side interconnect structure IS31 and including bonding metal features BM3 embedded in a boding layer BF3. In this embodiments, the bonding metal features BM3 include a bonding metal pad BMP31 and a bonding metal via BMV31 in direct contact with each other, and the bonding metal via BMV31 is in direct contact with a top metal feature of the front-side interconnect structure IS31. The materials and forming methods of the bonding metal features BM3 and the boding layer BF3 are similar to the materials and forming methods of the bonding metal features BM1 and the boding layer BF1, so the details are not iterated herein.

In some embodiments, the integrated circuit structure 12 further includes a redistribution layer structure RDL2. The redistribution layer structure RDL2 is disposed over and electrically connected to the backside interconnect structure IS32 of the die 400. The redistribution layer structure RDL2 may include metal features 424 embedded by dielectric layers 426 and electrically connected to each other. The materials and forming methods of the bonding metal features 424 and the dielectric layers 426 are similar to the materials and forming methods of the bonding metal features 124 and the dielectric layers 126, so the details are not iterated herein.

In some embodiments, the integrated circuit structure 12 further includes conductive terminals or bumps B. The bumps B are disposed over and electrically connected to the redistribution layer structure RDL2.

FIG. 8 illustrates a cross-sectional view of an integrated circuit structure in accordance with some embodiments of the present disclosure. Herein, similar elements are indicated by similar reference numerals, so the materials and forming methods of similar elements may refer to those described above, and the details are not iterated herein.

The integrated circuit structure 13 of FIG. 8 is similar to the integrated circuit structure 12 of FIG. 7, so the difference between them is described below, and the similarity is not iterated herein. In the integrated circuit structure 12, the bonding structure BS3 is formed over the front-side interconnect structure IS31 and then bonded to the underlying die 100, and the RDL2 is formed over the backside interconnect structure IS32 and then electrically connected to the overlying bumps B. However, in the integrated circuit structure 13, the bonding structure BS3 is formed over the backside interconnect structure IS32 and then bonded to the underlying die 100, and the RDL2 is formed over the front-side interconnect structure IS32 and then electrically connected to the overlying bumps B.

The present disclosure is directed to integrated circuit structures and forming methods thereof. The integrated circuit structure of the disclosure includes multiple dies vertically stacked, and interconnect structure(s) or power delivery network(s) may be placed on a single side or both sides of each die for routing flexibility. However, hot spots may generated in a die with both front-side and backside interconnect structures. In the disclosure, a heat dissipation structure is in direct contact with one die of the integrated circuit structure of the disclosure, so as to lower the device temperature and improve the device performance.

According to an aspect of the present disclosure, an integrated circuit structure includes a first die, a second die and the a heat dissipation structure. The first die includes a first device layer, a first front-side interconnect structure disposed on a front side of the first device layer, and a first backside interconnect structure disposed on a backside of the first device layer. The second die is bonded to the first die and includes a second device layer, and a second front-side interconnect structure disposed on a front side of the second device layer. The heat dissipation structure is in direct contact to the first die or the second die.

According to an aspect of the present disclosure, an integrated circuit structure includes a first die, a second die and the a heat dissipation carrier. The first die includes a first transistor disposed on a first substrate, a first front-side interconnect structure disposed on a front side of the first transistor and electrically connected to the first transistor, a first backside interconnect structure disposed on a back side of the first transistor and electrically connected to the first transistor through a metal via penetrating through the first substrate, and a first bonding structure disposed on and electrically connected to the first backside interconnect structure and comprising first bonding metal features embedded in a first boding layer. The second die bonded to the first die and includes a second transistor disposed on a second substrate, a second bonding structure disposed on and electrically connected to the second transistor, and comprising second bonding metal features embedded in a second boding layer, wherein the second bonding metal features are bonded to the first bonding metal features and the second bonding film is bonded to the first bonding film. The heat dissipation carrier attached to the first front-side interconnect structure of the first die through a first heat dissipation layer.

According to an aspect of the present disclosure, a method of forming an integrated circuit structure includes the following operations. A first die is placed on a carrier, wherein the first die includes a first front-side interconnect structure and a first backside interconnect structure electrically connected to each other, and the first backside interconnect structure of the first die faces the carrier. A first bonding structure is formed on the first front-side interconnect structure of the first die. A second die is placed on a heat dissipation carrier, wherein the second die includes a second front-side interconnect structure and a second backside interconnect structure electrically connected to each other, wherein the second backside interconnect structure faces the heat dissipation carrier. A second bonding structure is formed on the second backside interconnect structure of the second die. The second bonding structure of the second die is bonded to the first bonding structure of the first die.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit structure, comprising:
a first die, comprising:
a first transistor disposed on a first substrate;
a first front-side interconnect structure disposed on a front side of the first substrate and electrically connected to the first transistor;
a first backside interconnect structure disposed on a back side of the first substrate and electrically connected to the first transistor; and
a first bonding structure disposed on and electrically connected to the first backside interconnect structure and comprising first bonding metal features embedded in a first boding layer;
a second die bonded to the first die and comprising:
a second transistor disposed on a second substrate;
a second front-side interconnect structure disposed on a front side of the second substrate and electrically connected to the second transistor; and
a second bonding structure disposed on and electrically connected to the second front-side interconnect structure, and comprising second bonding metal features embedded in a second boding layer, wherein the second bonding metal features are bonded to the first bonding metal features and the second bonding film is bonded to the first bonding film; and
a heat dissipation structure attached to a back side of the second substrate of the second die.

2. The integrated circuit structure of claim 1, wherein the heat dissipation structure is in direct contact to the second substrate of the second die.

3. The integrated circuit structure of claim 1, wherein the heat dissipation structure comprises a first heat dissipation layer and a heat dissipation carrier, and the first heat dissipation layer is disposed between the second die and the heat dissipation carrier.

4. The integrated circuit structure of claim 3, wherein the first heat dissipation layer comprises AlN, GaN, ZnO, BN, Al₂O₃, HfO₂, TiO₂ or a combination thereof, and the heat dissipation carrier comprises a silicon carrier.

5. The integrated circuit structure of claim 3, wherein heat dissipation structure further comprises a second heat dissipation layer and a heat dissipation support, and the second heat dissipation layer is disposed between the heat dissipation carrier and the heat dissipation support.

6. The integrated circuit structure of claim 1, further comprising:
a redistribution layer structure disposed on and electrically connected to the first front-side interconnect structure; and
a bump disposed on and electrically connected to the redistribution layer structure.

7. The integrated circuit structure of claim 6, wherein a sidewall of the redistribution layer structure is flush with a sidewall of the first front-side interconnect structure.

8. The integrated circuit structure of claim 1, wherein the first backside interconnect structure is electrically connected to the first front-side interconnect structure through at least one metal via of about 0.01 μm to 0.1 μm thick within the first substrate.

9. An integrated circuit structure, comprising:
a first die comprising:
a first transistor disposed on a first substrate;
a first front-side interconnect structure disposed on a front side of the first substrate and electrically connected to the first transistor; and
a first bonding structure disposed on a back side of the first substrate and electrically connected to the first transistor, and comprising first bonding metal features embedded in a first boding layer;
a second die bonded to the first die and comprising:
a second transistor disposed on a second substrate; and
a second bonding structure disposed on and electrically connected to the second transistor, and comprising second bonding metal features embedded in a second boding layer, wherein the second bonding metal features are bonded to the first bonding metal features and the second bonding film is bonded to the first bonding film; and
a heat dissipation structure attached to the second die opposite to the second bonding structure.

10. The integrated circuit structure of claim 9, wherein the heat dissipation structure comprises at least one heat dissipation layer and at least one heat dissipation carrier in contact with each other.

11. The integrated circuit structure of claim 10, wherein the heat dissipation layer comprises AlN, GaN, ZnO, BN, Al₂O₃, HfO₂, TiO₂ or a combination thereof, and the heat dissipation carrier comprises a silicon carrier.

12. The integrated circuit structure of claim 11, wherein the heat dissipation layer is in contact with the second die.

13. The integrated circuit structure of claim 11, wherein the heat dissipation carrier is in contact with the second die.

14. The integrated circuit structure of claim 9, wherein the second die further comprises:
a second front-side interconnect structure disposed on a front side of the second substrate and electrically connected to the second transistor; and
a second backside interconnect structure disposed on a back side of the second substrate and electrically connected to the second transistor,
wherein the second bonding structure is disposed on the second backside interconnect structure, and
wherein the heat dissipation structure is in contact with the second front-side interconnect structure.

15. The integrated circuit structure of claim 9, wherein the second die further comprises:
a second front-side interconnect structure disposed on a front side of the second substrate and electrically connected to the second transistor; and
a second backside interconnect structure disposed on a back side of the second substrate and electrically connected to the second transistor,
wherein the second bonding structure is disposed on the second front-side interconnect structure, and
wherein the heat dissipation structure is in contact with the second backside interconnect structure.

16. The integrated circuit structure of claim 9, wherein the second die further comprises:
a second front-side interconnect structure disposed on a front side of the second substrate and electrically connected to the second transistor,
wherein the second bonding structure is disposed on the second front-side interconnect structure, and
wherein the heat dissipation structure is in contact with the second substrate.

17. A method of forming an integrated circuit structure, comprising:
placing a first die on a carrier, wherein the first die comprises a first front-side interconnect structure and a first backside interconnect structure electrically connected to each other, and the first front-side interconnect structure of the first die faces the carrier;
forming a first bonding structure on the first backside interconnect structure of the first die;
placing a second die on a heat dissipation carrier, wherein the second die comprises a second front-side interconnect opposite to the heat dissipation carrier;
forming a second bonding structure on the second front-side interconnect structure of the second die; and
bonding the second bonding structure of the second die to the first bonding structure of the first die.

18. The method of claim 17, further comprising:
forming a first heat dissipation layer between the heat dissipation carrier and the second die.

19. The method of claim 17, further comprising:
removing the carrier; and
forming a post-interconnect structure on the first backside interconnect structure of the first die.

20. The method of claim 19, wherein a sidewall of the post-interconnect structure is flush with a sidewall of the first front-side interconnect structure.
